(19) United States
(12) Patent Application Publication
(10) Pub. No.: US 2025/0234730 A1
(43) Pub. Date: Jul. 17, 2025

(54) DISPLAY PANEL AND MANUFACTURING METHOD OF THE SAME

(71) Applicant: Samsung Display Co., Ltd., Yongin-si (KR)

(72) Inventors: KWANGSOO LEE, Yongin-si (KR); JEONGJU PARK, Yongin-si (KR); WOOGEUN LEE, Yongin-si (KR)

(21) Appl. No.: 18/934,909

(22) Filed: Nov. 1, 2024

(30) Foreign Application Priority Data
Jan. 15, 2024 (KR) 10-2024-0006150

(51) Int. Cl. H10K 59/131; G09G 3/3225; H10K 59/12; H10K 59/124

(52) U.S. Cl. CPC H10K 59/131; G09G 3/3225; H10K 59/1201; H10K 59/124; G09G 2360/147

(57) ABSTRACT

A display panel including a base layer, a transistor on the base layer and including a semiconductor pattern, a first connection electrode connected to the semiconductor pattern, a sensing line at a same layer as the first connection electrode, a first insulating layer on the transistor and the first connection electrode, a second insulating layer on the first insulating layer, a first electrode on the second insulating layer and connected to the connection electrode through a first through-hole, an additional electrode on the second insulating layer, the additional electrode being spaced from the first electrode in a plan view, and connected to the sensing line through a second through-hole, and a sensing pattern on the first insulating layer, the sensing pattern being electrically connected to the first electrode and the additional electrode, and including silicon.

### CROSS-REFERENCE TO RELATED APPLICATION

The present application claims priority to and the benefit of Korean Patent Application No. 10-2024-0006150, filed on Jan. 15, 2024, in the Korean Intellectual Property Office, the entire content of which is incorporated by reference herein.

### BACKGROUND

### 1. Field

The present disclosure herein relates to a display panel and a manufacturing method of the same, and more particularly, to a display panel having improved light emission efficiency and power consumption and a manufacturing method of the same.

### 2. Description of the Related Art

Multimedia devices such as televisions, mobile phones, tablet PCs, computers, navigation devices, and game consoles may include a display panel for displaying an image. The display panel may include a plurality of pixels for displaying an image, and each of the pixels may include a light-emitting element which generates light and a driving element which is connected to the light-emitting element.

The light-emitting element and the driving element of the display panel may be formed through stacking a thin film and patterning the thin film using a mask. Because a manufacturing process for a display panel using a mask is expensive, it is necessary to simplify a manufacturing process for a display panel to reduce the number of masks required for manufacturing a display device. Also, it is required to manufacture a display panel having improved light emission efficiency and power consumption while a manufacturing process is simplified.

### SUMMARY

The present disclosure provides a display panel having improved light emission efficiency and power consumption.

The present disclosure provides a manufacturing method of a display panel having an improved manufacturing process efficiency.

One or more embodiments of the present disclosure provide a display panel including a base layer, a transistor on the base layer and including a semiconductor pattern, a first connection electrode connected to the semiconductor pattern, a sensing line at a same layer as the first connection electrode, a first insulating layer on the transistor and the first connection electrode, a second insulating layer on the first insulating layer, a first electrode on the second insulating layer and connected to the connection electrode through a first through-hole, an additional electrode on the second insulating layer, the additional electrode being spaced from the first electrode in a plan view, and connected to the sensing line through a second through-hole, and a sensing pattern on the first insulating layer, the sensing pattern being electrically connected to the first electrode and the additional electrode, and including silicon.

In one or more embodiments, a light transmittance of the sensing pattern in a visible light wavelength range may be about 10% or more.

In one or more embodiments, the display panel may further include a gate insulating pattern layer on the semiconductor pattern. Each of the first connection electrode and the sensing line may be on the gate insulating pattern layer.

In one or more embodiments, the transistor may further include a gate electrode on the gate insulating pattern layer.

In one or more embodiments, the first connection electrode, the sensing line, and the gate electrode may include a same material.

In one or more embodiments, the sensing pattern may include the silicon and nitrogen.

In one or more embodiments, the display panel may further include an intermediate layer on the first electrode and including an emission layer, and a second electrode on the intermediate layer.

In one or more embodiments, the first electrode and the additional electrode may be spaced from each other along a first direction. A width of the first electrode in the first direction may be greater than a width of the additional electrode in the first direction.

In one or more embodiments, a distance between the first electrode and the additional electrode in the first direction may be greater than the width of the additional electrode in the first direction.

In one or more embodiments, a length of the first electrode in a second direction crossing the first direction may be substantially the same as a length of the additional electrode in the second direction.

In one or more embodiments, each of the first through-hole and the second through-hole may pass through each of the first insulating layer, the second insulating layer, and the sensing pattern.

In one or more embodiments, each of the first through-hole and the second through-hole may be include a plurality of through-holes.

In one or more embodiments, the first electrode and the additional electrode may be spaced from each other along a first direction. Each of the first through-hole and the second through-hole may include a long side extending in a second direction crossing the first direction, and a short side extending in the first direction.

In one or more embodiments, the display panel may further include a lower insulating layer between the base layer and the transistor, and a plurality of conductive patterns between the lower insulating layer and the base layer and spaced from each other in a plan view. At least a portion of the plurality of conductive patterns may be electrically connected to the first connection electrode.

In one or more embodiments, the display panel may further include a pixel-defining layer on the second insulating layer and having a pixel opening located therein and exposing at least a portion of the first electrode. The additional electrode may be covered with the pixel-defining layer.

In one or more embodiments, a light transmittance of the second insulating layer in a visible light wavelength range may be about 80% or more.

In an embodiment of the present disclosure, a display panel includes a base layer, a transistor on the base layer and including a semiconductor pattern, a first connection electrode connected to the semiconductor pattern, a sensing line spaced from the first connection electrode in a plan view, a first insulating layer on the transistor and the first connection electrode, a second insulating layer on the first insulating layer, a light-emitting element on the second insulating layer and electrically connected to the first connection electrode, an additional electrode on the second insulating layer and connected to the sensing line, and a sensing pattern on the first insulating layer. The light-emitting element includes a first electrode on the second insulating layer, connected to the first connection electrode, and spaced from the additional electrode in a plan view, an emission layer on the first electrode, and a second electrode on the emission layer. A portion of each of the first electrode and the additional electrode is in a through-hole in the sensing pattern.

In one or more embodiments, the display panel may further include a pixel-defining layer on the second insulating layer and having a pixel opening defined therein and exposing at least a portion of the first electrode. The additional electrode may be covered with the pixel-defining layer.

In one or more embodiments of the present disclosure, a manufacturing method of a display panel includes forming a semiconductor pattern on a base layer, forming a gate insulating pattern layer covering a portion of the semiconductor pattern, forming a first connection electrode and a sensing line on the gate insulating pattern layer, forming a first insulating layer covering the first connection electrode and the sensing line, forming a sensing pattern including silicon on the first insulating layer, forming a second insulating layer covering the sensing pattern, forming each of a first through-hole and a second through-hole passing through the first insulating layer, the sensing pattern, and the second insulating layer, and forming, on the second insulating layer, a first electrode connected to the first connection electrode through the first through-hole, and an additional electrode connected to the sensing line through the second through-hole.

In one or more embodiments, in the forming of the sensing pattern, nitrogen (N₂) gas and silane (SiH₄) gas may be provided. A ratio of the nitrogen gas to the silane gas may be about 4.0 to about 10.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to one or more embodiments of the present disclosure;

FIG. 2A is an exploded perspective view of a display device according to one or more embodiments of the present disclosure;

FIG. 2B is a cross-sectional view of a display module according to one or more embodiments of the present disclosure;

FIG. 3 is a plan view of a display panel according to one or more embodiments of the present disclosure;

FIG. 4 is a cross-sectional view of a portion of a display module according to one or more embodiments of the present disclosure;

FIG. 5 is a cross-sectional view of a display panel according to one or more embodiments of the present disclosure;

FIGS. 6A and 6B each are a plan view of some components of a display panel according to one or more embodiments of the present disclosure;

FIG. 7 is a plan view of some components of a display panel according to one or more embodiments of the present disclosure;

FIGS. 8A-8E each are a plan view of some components of a display panel according to one or more embodiments of the present disclosure;

FIG. 9 is a cross-sectional view of a display panel according to one or more embodiments of the present disclosure;

FIG. 10 is a flowchart of a manufacturing method of a display panel according to one or more embodiments of the present disclosure;

FIGS. 11A-11D are cross-sectional views of some steps of a manufacturing method of a display panel according to one or more embodiments of the present disclosure;

FIG. 12A is a graph showing a value of a leakage current compared to a voltage of a sensing pattern according to the amount of emitted light of a light-emitting element in a display panel according to one or more embodiments; and

FIG. 12B is a graph showing a value of a leakage current compared to the amount of emitted light of a light-emitting element according to a voltage applied to a sensing pattern in a display panel according to one or more embodiments.

### DETAILED DESCRIPTION

Hereinafter, embodiments of the present disclosure will be described with reference to the accompanying drawings.

In this specification, it will be understood that when an element (or a region, a layer, a portion, or the like) is referred to as being “on”, “connected to” or “coupled to” another element, it may be directly connected or coupled to the other element, or an intervening element may be disposed therebetween.

Like numerals or symbols refer to like elements throughout. Also, in the drawings, the thicknesses, ratios, and dimensions of the elements are exaggerated for effective description of the technical contents. The term “and/or” includes all of one or more combinations which the associated elements may define.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the spirit and scope of the present disclosure. The singular forms include the plural forms as well unless the context clearly indicates otherwise.

Also, terms such as “below”, “on lower side”, “above”, and “on upper side” are used to describe the relationships of the elements illustrated in the drawings. These terms have relative concepts and are described on the basis of the directions indicated in the drawings.

It will be understood that the terms such as “include” or “have”, when used herein, are intended to specify the presence of stated features, integers, steps, operations, elements, components, or combinations thereof, but do not preclude the presence or addition of one or more other features, integers, steps, operations, elements, components, and/or combinations thereof.

As used herein, “directly disposed” may mean that there is no layer, film, region, plate, etc. added between a portion such as a layer, film, region, or plate and another portion. For example, “directly disposed” may mean that two layers or two members are disposed without using an additional member such as an adhesive member therebetween.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized and/or overly formal sense unless expressly so defined herein.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, a display panel according to one or more embodiments of the present disclosure and a manufacturing method of a display panel will be described with reference to the accompanying drawings.

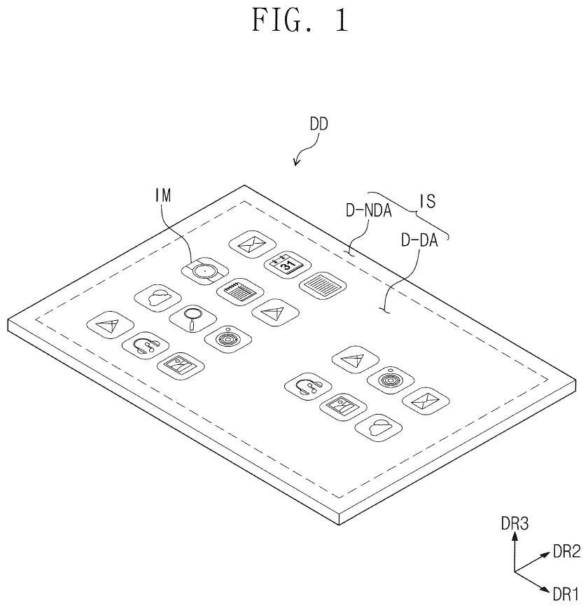

FIG. 1 is a perspective view of a display device according to one or more embodiments of the present disclosure.

Referring to FIG. 1, a display device DD may be activated in response to an electrical signal and display an image. The display device DD may include various embodiments which provide an image IM to a user, and for example, the display device DD may be a large-sized device such as a television and an outdoor billboard as well as a small or medium-sized device such as a monitor, a mobile phone, a tablet PC, a navigation device, and a game console. However, embodiments of the display device DD are used as examples, and the display device DD is not limited to any one embodiment, and would apply to any suitable embodiment provided that the display device DD does not depart from the scope of the present disclosure.

The display device DD may have a rectangular shape having long sides extending in a first direction DR1 and short sides extending in a second direction DR2 in a plan view. However, the present disclosure is not limited thereto, and the display device DD may have various shapes such as a circle and/or a polygon.

The display device DD may display the image IM in a third direction DR3 (e.g., a thickness direction of the display device DD) through a display surface IS parallel to a plane defined by the first direction DR1 and the second direction DR2. The third direction DR3 may be substantially parallel to a normal direction of the display surface IS. The display surface IS on which the image IM is displayed may correspond to a front surface of the display device DD. The image IM may include a static image as well as a dynamic image. FIG. 1 illustrates icon images as an example of the image IM.

In this embodiment, a front surface (or an upper surface) and a rear surface (or a lower surface) of each member constituting the display device DD may be defined on the basis of the third direction DR3. A front surface and a rear surface may be opposed to (e.g., opposite) each other in the third direction DR3, and a normal direction of each of a front surface and a rear surface may be parallel to the third direction DR3. A distance between a front surface and a rear surface defined along the third direction DR3 may correspond to a thickness of a member.

As used herein, the wording “in a plan view” may be defined as a state of being viewed in the third direction DR3. As used herein, the wording “in a cross-sectional view” may be defined as a state of being viewed in the first direction DR1 or the second direction DR2. However, directions indicated by the first to third directions DR1, DR2, and DR3 may have a relative concept and may thus be changed to other directions.

FIG. 1 illustrates as an example the display device DD having a flat display surface IS. However, a form of the display surface IS of the display device DD is not limited thereto, and the display surface IS may be a curved display surface and/or a three-dimensional display surface.

The display device DD may be flexible. “Flexible” may imply a bendable property, and the display device DD may be a device including any one from among a structure which is completely foldable to a structure which is bendable to a level of several nanometers. For example, the flexible display device DD may include a curved device and/or a foldable device. However, the present disclosure is not limited thereto, and the display device DD may be rigid.

The display surface IS of the display device DD may include a display portion D-DA and a non-display portion D-NDA disposed around the display portion D-DA along an edge or a periphery of the display portion D-DA. The display portion D-DA may be a portion in which the image IM is displayed in the front surface of the display device DD, and a user may view the image IM through the display portion D-DA. In this embodiment, a display portion D-DA having a quadrangular shape in a plan view is illustrated as an example, but the display portion D-DA may have various shapes according to a design of the display device DD.

The non-display portion D-NDA may be a portion in which the image IM is not displayed in the front surface of the display device DD. The non-display portion D-NDA may be a portion which has a suitable color (e.g., a predetermined color) and blocks light. The non-display portion D-NDA may be adjacent to the display portion D-DA. For example, the non-display portion D-NDA may be disposed outside the display portion D-DA and surround the display portion D-DA. However, this is illustrated as an example, and the non-display portion D-NDA may be adjacent to only one side of the display portion D-DA or disposed on a side surface, not the front surface, of the display device DD. The present disclosure is not limited thereto, and the non-display portion D-NDA may also be omitted.

In one or more embodiments, the display device DD may sense an external input applied from the outside. The external input may have various forms such as temperature, light, and pressure provided from the outside. The external input may include not only an input that contacts the display device DD (e.g., a contact by a user's hand or a pen), but also an input applied close to the display device DD (e.g., hovering).

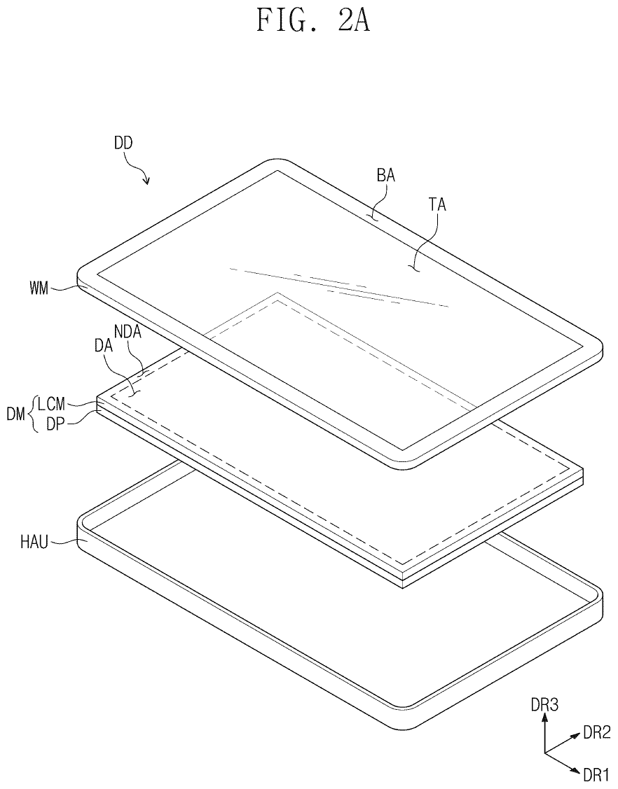

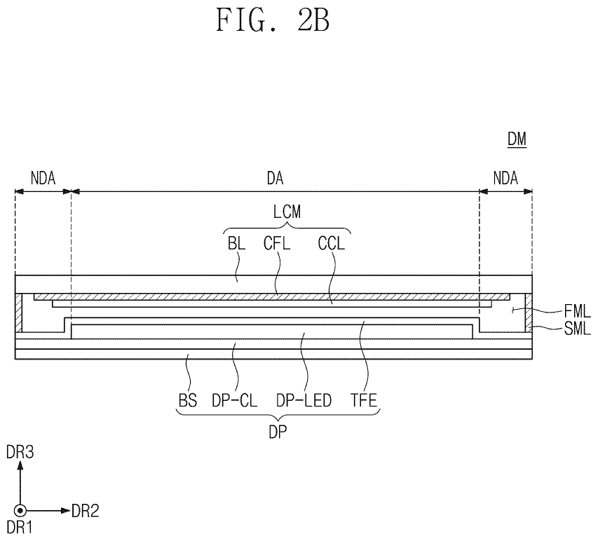

FIG. 2A is an exploded perspective view of a display device according to one or more embodiments of the present disclosure. FIG. 2B is a cross-sectional view of a display module according to one or more embodiments of the present disclosure.

Referring to FIGS. 2A and 2B, a display device DD may include a window WM, a display module DM, and a housing HAU. The display module DM may include a display panel DP and a light control member LCM disposed on the display panel DP.

The window WM and the housing HAU may be coupled to each other to form an exterior of the display device DD and to provide an inner space capable of accommodating components of the display device DD such as the display module DM.

The window WM may be disposed on the display module DM. The window WM may protect the display module DM from an external impact. A front surface of the window WM may correspond to the display surface IS of the display device DD described above. The front surface of the window WM may include a transmission region TA and a bezel region BA.

The transmission region TA of the window WM may be an optically transparent region. The window WM may transmit an image provided by the display module DM through the transmission region TA, and a user may view the image. The transmission region TA may correspond to the display portion D-DA of the display device DD described above.

The window WM may include an optically transparent insulating material. For example, the window WM may include glass, sapphire, and/or plastic. The window WM may have a single-layered structure or multi-layered structure. The window WM may further include a functional layer such as an anti-fingerprint layer, a phase control layer, and/or a hard coating layer disposed on an optically transparent substrate.

The bezel region BA of the window WM may be provided as a region in which a material having a suitable color (e.g., a predetermined color) is deposited, applied, and/or printed on a transparent substrate. The bezel region BA of the window WM may prevent a component of the display module DM disposed to overlap the bezel region BA from being viewed from the outside. The bezel region BA may correspond to the non-display portion D-NDA of the display device DD described above.

The display module DM may be disposed between the window WM and the housing HAU. The display module DM may display an image in response to an electrical signal. The display module DM may include a display region DA and a non-display region NDA adjacent to the display region DA. The non-display region NDA may be around the display region DA along an edge or a periphery of the display region DA.

The display region DA may be a region which is activated in response to an electrical signal and in which an image is outputted or displayed. The display region DA of the display module DM may overlap the transmission region TA of the window WM. As used herein, the wording “a region/portion and a region/portion overlap each other” is not limited to a case in which regions/portions have the same area size and/or the same shape. The image outputted from the display region DA may be viewed from the outside through the transmission region TA.

The non-display region NDA may be adjacent to the display region DA. For example, the non-display region NDA may surround the display region DA. However, the present disclosure is not limited thereto, and the non-display region NDA may be defined in various shapes. The non-display region NDA may be a region in which a driving line or a driving circuit for driving elements disposed in the display region DA, various types of signal lines for providing an electrical signal, and pads are disposed. The non-display region NDA of the display module DM may overlap the bezel region BA of the window WM, and components disposed in the non-display region NDA may be prevented from being viewed from the outside by the bezel region BA.

The display panel DP according to one or more embodiments may be an emissive display panel, and is not particularly limited thereto. For example, the display panel DP may be an organic light-emitting display panel, an inorganic light-emitting display panel, and/or a quantum dot light-emitting display panel. An emission layer of the organic light-emitting display panel may include an organic light-emitting material, and an emission layer of the inorganic light-emitting display panel may include an inorganic light-emitting material. An emission layer of the quantum dot light-emitting display panel may include a quantum dot, a quantum rod, etc. Hereinafter, the display panel DP will be described as an organic light-emitting display panel.

The display panel DP may include a base layer BS, a circuit element layer DP-CL, a display element layer DP-LED, and an encapsulation layer TFE.

The base layer BS may provide a base surface on which the circuit element layer DP-CL is disposed. The base layer BS may be a rigid substrate, but is not limited thereto and may be a flexible substrate.

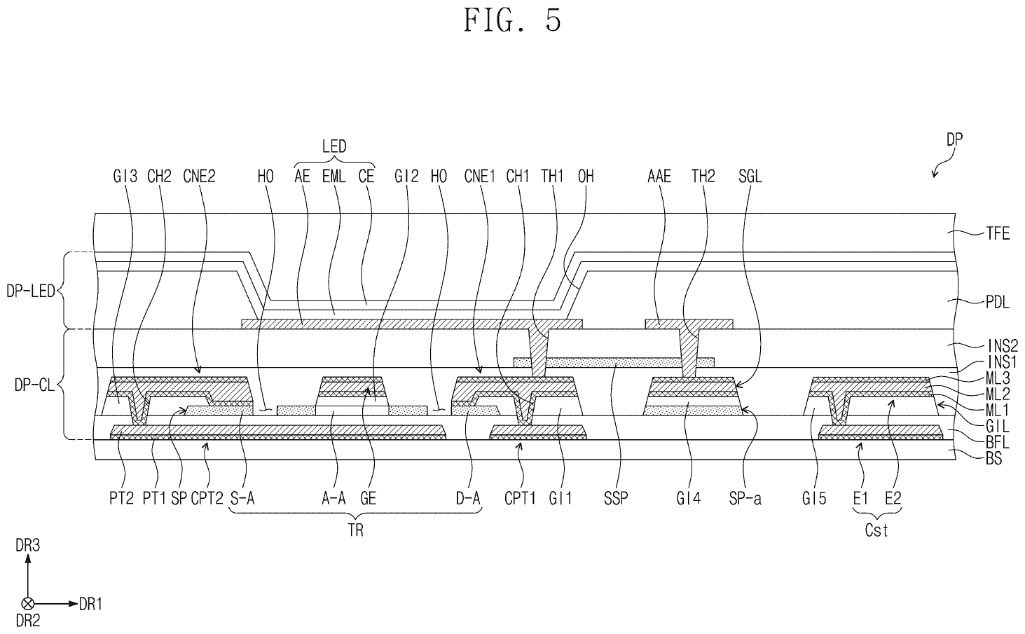

The circuit element layer DP-CL may be disposed on the base layer BS. The circuit element layer DP-CL may include driving elements such as a transistor, signal lines, and/or signal pads. The display element layer DP-LED may include light-emitting elements disposed to overlap the display region DA. The light-emitting elements of the display element layer DP-LED may be electrically connected to the driving elements of the circuit element layer DP-CL and output light through the display region DA in response to a signal from the driving elements. The configuration of the circuit element layer DP-CL will be described in detail with reference to FIG. 5 and subsequent drawings.

The encapsulation layer TFE may be disposed on the display element layer DP-LED and encapsulate the light-emitting elements. The encapsulation layer TFE may include a plurality of thin films. The thin films of the encapsulation layer TFE may be disposed to improve optical efficiency of the light-emitting elements or protect the light-emitting elements.

The light control member LCM may be disposed on the display panel DP. The light control member LCM may be provided on the display panel DP, and then coupled to the display panel DP through a bonding process using a sealing member SML.

However, the present disclosure is not limited thereto, and the light control member LCM may be directly disposed on the display panel DP. As used herein, the expression “directly disposed” may indicate being formed through a continuous process without disposition of a separate adhesive layer or adhesive member. For example, the expression “the light control member LCM is directly disposed on the display panel DP” may indicate that the display panel DP is formed, and then the light control member LCM is formed on a base surface provided by the display panel DP through a continuous process.

The light control member LCM may convert a wavelength of light provided from the display panel DP, that is, source light, or selectively transmit the source light. For example, the light control member LCM may include light control patterns capable of converting an optical property of the source light provided from the display panel DP. The light control member LCM may control color purity or color gamut of light emitted from the display device DD and prevent reflection of external light incident from outside the display device DD.

The light control member LCM may include a base layer BL, a color filter layer CFL, and a light control layer CCL. The base layer BL may be disposed to face the base layer BS of the display panel DP, and the color filter layer CFL and the light control layer CCL disposed on the base layer BL may be located between the display panel DP and the base layer BL.

The light control layer CCL may include a quantum dot which converts a wavelength of the source light provided from the display panel DP, or may further include a transmission portion that transmits the source light. The source light that has passed through the quantum dot included in the light control layer CCL may be outputted as light having a color different from that of the source light.

The color filter layer CFL may include color filters, and the color filters may transmit and/or absorb light passed through the light control layer CCL according to a color of light. The color filter layer CFL may absorb light that is not converted by the light control layer CCL, thereby preventing color purity of the display device DD from being deteriorated. In addition, the color filter layer CFL may filter external light to the same color as that of pixels, thereby preventing or reducing external light reflection.

The sealing member SML may be disposed in the non-display region NDA, which is an outer peripheral portion of the display module DM, and prevent foreign substances, oxygen, moisture, etc. from being introduced into the display module DM from outside the display module DM. The sealing member SML may be formed from sealant including a curable resin.

The display module DM according to one or more embodiments may further include a filling layer FML disposed between the display panel DP and the light control member LCM. The filling layer FML may fill a space between the display panel DP and the light control member LCM. The filling layer FML may function as a buffer between the display panel DP and the light control member LCM. In one or more embodiments, the filling layer FML may absorb an impact and increase strength of the display module DM.

The filling layer FML may be formed from a filling resin including a polymer resin. For example, the filling layer FML may include an acrylic resin, an epoxy-based resin, and/or the like. However, because the light control member LCM according to one or more embodiments may be directly disposed on the display panel DP, the filling layer FML and the sealing member SML may be omitted. In one or more embodiments in which the light control member LCM is directly disposed on the display panel DP, the base layer BL of the light control member LCM may be omitted.

The housing HAU may be disposed under the display module DM and accommodate the display module DM. The housing HAU may protect the display module DM by absorbing an impact applied to the display module DM from the outside and preventing foreign substances and/or moisture, etc. from being introduced into the display module DM. The housing HAU according to one or more embodiments may be provided in a form in which a plurality of accommodation members are coupled to each other.

In one or more embodiments, the display device DD may further include an input sensing module. The input sensing module may acquire coordinate information about an external input applied from outside the display device DD. The input sensing module may be driven using various methods such as a capacitive method, a resistive method, an infrared method, and/or a pressure method, and is not limited thereto.

In one or more embodiments, the input sensing module may be disposed on the display module DM. The input sensing module may be directly disposed on the display module DM through a continuous process, but is not limited thereto and may be manufactured separately from the display module DM and attached onto the display module DM by an adhesive layer. However, the present disclosure is not limited thereto, and the input sensing module may be disposed between components of the display module DM. For example, the input sensing module may be disposed between the display panel DP and the light control member LCM.

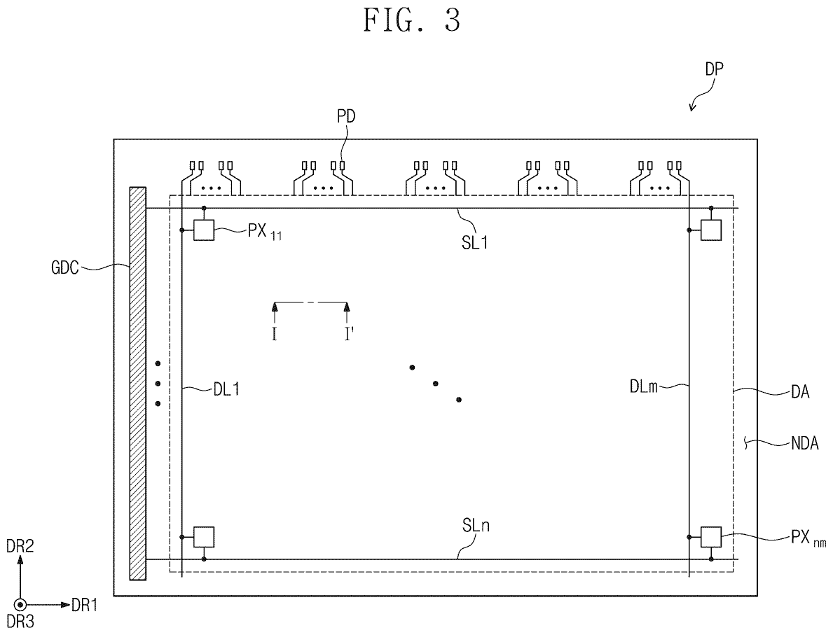

FIG. 3 is a plan view of a display panel according to one or more embodiments of the present disclosure.

Referring to FIG. 3, a display panel DP may include pixels PX₁₁ to PXₙₘ disposed in a display region DA and signal lines SL1 to SLn and DL1 to DLm electrically connected to the pixels PX₁₁ to PXₙₘ. The display panel DP may include pads PD and a driving circuit GDC disposed in a non-display region NDA.

Each of the pixels PX₁₁ to PXₙₘ may include a pixel driving circuit including a light-emitting element, a plurality of transistors (e.g., a switching transistor, a driving transistor, etc.) connected to the light-emitting element, and a capacitor. The pixels PX₁₁ to PXₙₘ may emit light in response to an electrical signal applied to the pixels PX₁₁ to PXₙₘ. FIG. 3 illustrates as an example the pixels PX₁₁ to PXₙₘ arranged in a matrix form, but an arrangement of the pixels PX₁₁ to PXₙₘ is not limited thereto.

The signal lines SL1 to SLn and DL1 to DLm may include scan lines SL1 to SLn and data lines DL1 to DLm. Each of the pixels PX₁₁ to PXₙₘ may be connected to a corresponding scan line from among the scan lines SL1 to SLn and a corresponding data line from among the data lines DL1 to DLm. More various types of signal lines may be included in the display panel DP according to the configuration of the pixel driving circuit of the pixels PX₁₁ to PXₙₘ.

The driving circuit GDC may include a gate driving circuit. The gate driving circuit may generate gate signals and sequentially output the gate signals to the scan lines SL1 to SLn. The gate driving circuit may further output another control signal to the pixel driving circuit of the pixels PX₁₁ to PXₙₘ.

The driving circuit GDC and the pixels PX₁₁ to PXₙₘ according to one or more embodiments may include a plurality of transistors formed through a low temperature polycrystalline silicon (LTPS) process, a low temperature polycrystalline oxide (LTPO) process, and/or an oxide semiconductor process.

The pads PD may be arranged in the non-display region NDA along one direction. The pads PD may be portions connected to a circuit board. Each of the pads PD may be connected to a corresponding signal line from among the signal lines SL1 to SLn and DL1 to DLm, and connected to a corresponding pixel from among PX₁₁ to PXₙₘ through the signal line. The pads PD may have an integrated shape with the signal lines SL1 to SLn and DL1 to DLm. However, the present disclosure is not limited thereto, and the pads PD and the signal lines SL1 to SLn and DL1 to DLm may be disposed on different layers, and the pads PD may be connected to the signal lines SL1 to SLn and DL1 to DLm through a contact hole.

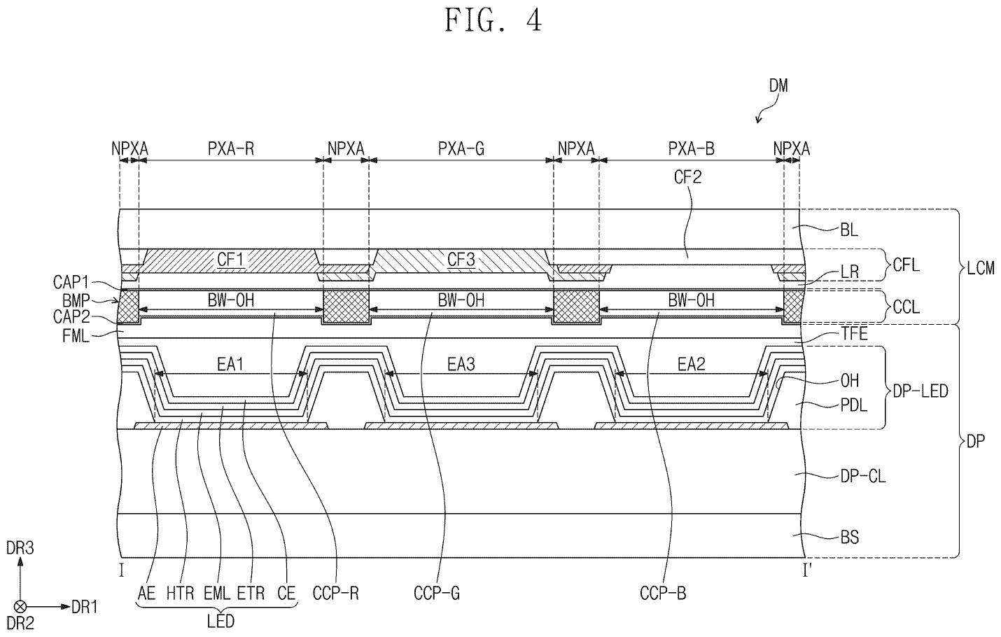

FIG. 4 is a cross-sectional view of a portion of a display module according to one or more embodiments of the present disclosure. FIG. 4 illustrates a cross section of a display panel and a light control member disposed on the display panel taken along the line I-I′ illustrated in FIG. 3.

Referring to FIG. 4, a display module DM may include a display panel DP including a base layer BS, a circuit element layer DP-CL disposed on the base layer BS, and a display element layer DP-LED disposed on the circuit element layer DP-CL, and a light control member LCM disposed on the display panel DP. The light control member LCM may include a light control layer CCL, a color filter layer CFL, and a base layer BL. In this specification, the display panel DP may be referred to as a lower panel, and the light control member LCM may be referred to as an upper panel.

The display panel DP may include the base layer BS and the circuit element layer DP-CL disposed on the base layer BS. The circuit element layer DP-CL may be disposed on the base layer BS. The circuit element layer DP-CL may include an insulating layer, a semiconductor pattern, a conductive pattern, a signal line, and/or the like. An insulating layer, a semiconductor layer, and/or a conductive layer may be formed on the base layer BS through coating, depositing, and/or the like, and then, the insulating layer, the semiconductor layer, and/or the conductive layer may be selectively patterned through a photolithography process performed multiple times. Thereafter, the semiconductor pattern, the conductive pattern, and/or the signal line included in the circuit element layer DP-CL may be formed. In one or more embodiments, the circuit element layer DP-CL may include a transistor, a buffer layer, and/or a plurality of insulating layers. The configuration of the circuit element layer DP-CL will be described in detail with reference to FIG. 5 and subsequent drawings.

A light-emitting element LED according to one or more embodiments may include a first electrode AE, a second electrode CE facing the first electrode AE, and an emission layer EML disposed between the first electrode AE and the second electrode CE. The emission layer EML included in the light-emitting element LED may include an organic light-emitting material as a light-emitting material and/or include a quantum dot as a light-emitting material. The light-emitting element LED may further include a hole control layer HTR and an electron control layer ETR. In one or more embodiments, the light-emitting element LED may further include a capping layer disposed on the second electrode CE.

A pixel-defining layer PDL may be disposed on the circuit element layer DP-CL and cover a portion of the first electrode AE. A light-emitting opening OH is defined in the pixel-defining layer PDL. The light-emitting opening OH of the pixel-defining layer PDL exposes at least a portion of the first electrode AE. In this embodiment, light-emitting regions EA1, EA2, and EA3 is defined to correspond to a partial region of the first electrode AE exposed by the light-emitting opening OH.

The display element layer DP-LED may include a first light-emitting region EA1, a second light-emitting region EA2, and a third light-emitting region EA3. The first light-emitting region EA1, the second light-emitting region EA2, and the third light-emitting region EA3 may be regions separated from each other by the pixel-defining layer PDL. The first light-emitting region EA1, the second light-emitting region EA2, and the third light-emitting region EA3 may respectively correspond to a first pixel region PXA-R, a second pixel region PXA-B, and a third pixel region PXA-G.

The light-emitting regions EA1, EA2, and EA3 may overlap pixel regions PXA-R, PXA-B, and PXA-G. In a plan view, an area size of the pixel regions PXA-R, PXA-B, and PXA-G separated from each other by color filters CF1, CF2, and CF3 may be substantially the same as an area size of the light-emitting regions EA1, EA2, and EA3 separated from each other by the pixel-defining layer PDL.

The first electrode AE in the light-emitting element LED is disposed on the circuit element layer DP-CL. The first electrode AE may be an anode or a cathode. Also, the first electrode AE may be a pixel electrode. The first electrode AE may be a transmissive electrode, a transflective electrode, or a reflective electrode.

The light-emitting element LED includes at least the emission layer EML. In one or more embodiments, the emission layer EML may be provided as a common layer so as to overlap all of the light-emitting regions EA1, EA2, and EA3 and the pixel-defining layer PDL that separates the light-emitting regions EA1, EA2, and EA3. In one or more embodiments, the emission layer EML may emit blue light. The emission layer EML may entirely overlap the electron control layer ETR and the hole control layer HTR.

However, the present disclosure is not limited thereto, and in one or more embodiments, the emission layer EML may be disposed in the light-emitting opening OH. That is, the emission layer EML may be separately formed to correspond to the light-emitting regions EA1, EA2, and EA3 separated from each other by the pixel-defining layer PDL. The emission layers EML separately formed to correspond to the light-emitting regions EA1, EA2, and EA3 may all emit blue light or may also emit light having different wavelength ranges.

The emission layer EML may have a single-layered structure formed of a single material, a single-layered structure formed of a plurality of materials different from each other, or a multi-layered structure having a plurality of layers formed of a plurality of materials different from each other. The emission layer EML may include a fluorescent and/or phosphorescent material. The emission layer EML in the light-emitting element according to one or more embodiments may include an organic light-emitting material, a metal organic complex, a quantum dot, and/or the like as a light-emitting material. FIGS. 3 and 4 illustrate as examples, the light-emitting element LED including one emission layer EML, but in one or more embodiments, the light-emitting element LED may also include a plurality of light-emitting stacks each including at least one emission layer.

The light-emitting element LED may emit light in a direction from the first electrode AE to the second electrode CE. In the light-emitting element LED according to one or more embodiments, the hole control layer HTR may transfer holes provided from the first electrode AE to the emission layer EML. The electron control layer ETR may transfer electrons provided from the second electrode CE to the emission layer EML.

It is illustrated as an example that, with respect to a direction in which light is emitted, the light-emitting element LED according to one or more embodiments has a structure in which the hole control layer HTR is disposed below the emission layer EML, and the electron control layer ETR is disposed above the emission layer EML. That is, the light-emitting element LED according to one or more embodiments may have a forward element structure. However, the present disclosure is not limited thereto, and with respect to a direction in which light is emitted, the light-emitting element LED may also have an inverted element structure in which the electron control layer ETR is disposed below the emission layer EML, and the hole control layer HTR is disposed above the emission layer EML.

The hole control layer HTR may include a hole injection layer and a hole transport layer disposed on the hole injection layer. The hole transport layer may be in contact with a lower surface of the emission layer EML. However, the present disclosure is not limited thereto, and the hole control layer HTR may further include a hole-side additional layer disposed on the hole transport layer. The hole-side additional layer may include at least one of a hole buffer layer, an emission auxiliary layer, or an electron blocking layer. The hole buffer layer may be a layer that compensates for a resonance distance according to a wavelength of light emitted from the emission layer and increases light emission efficiency. The electron blocking layer may be a layer that serves to prevent an electron from being injected from an electron transport region to a hole transport region.

The electron control layer ETR may include an electron transport layer. The electron control layer ETR may further include an electron injection layer disposed on the electron transport layer. The electron control layer ETR may further include an electron-side additional layer disposed between the electron transport layer and the emission layer EML. The electron-side additional layer may include at least one of an electron buffer layer or a hole blocking layer.

In the light-emitting element LED according to one or more embodiments, the first electrode AE may be a reflective electrode. For example, the first electrode AE may include highly reflective metal, such as Ag, Mg, Cu, Al, Pt, Pd, Au, Ni, Nd, Ir, Cr, Li, Ca, LiF/Ca, LiF/AI, Mo, Ti, W, In, Zn, Sn, and/or a compound and/or mixture (e.g., a mixture of Ag and Mg) thereof. Alternatively, the first electrode AE may have a multi-layered structure including a reflective film formed of the material and a transparent conductive film formed of indium tin oxide (ITO), indium zinc oxide (IZO), zinc oxide (ZnO), indium tin zinc oxide (ITZO), etc. For example, the first electrode AE may have a two-layered structure of ITO/Ag and a three-layered structure of ITO/Ag/ITO, but is not limited thereto. In addition, the present disclosure is not limited thereto, and the first electrode AE may include the metal material described above, a combination of two or more metal materials selected from among the metal materials described above, or an oxide of the metal materials described above, etc. A thickness of the first electrode AE may be about 70 nm to about 1000 nm. For example, a thickness of the first electrode AE may be about 100 nm to about 300 nm.

In the light-emitting element LED according to one or more embodiments, the hole control layer HTR may have a single-layered structure formed of a single material, a single-layered structure formed of a plurality of materials different from each other, or a multi-layered structure having a plurality of layers formed of a plurality of materials different from each other.

The hole control layer HTR may be formed by using various methods such as a vacuum deposition method, a spin coating method, a casting method, a Langmuir-Blodgett (LB) method, an inkjet printing method, a laser printing method, and/or a laser induced thermal imaging (LITI) method.

The hole control layer HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-I-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole control layer HTR may also include a carbazole-based derivative such as N-phenyl carbazole and polyvinyl carbazole, a fluorene-based derivative, N,N′-bis(3-methylphenyl)-N,N′-diphenyl-[1,1′-biphenyl]-4,4′-diamine (TPD), a triphenylamine-based derivative such as 4,4′,4″-tris(N-carbazolyl)triphenylamine (TCTA), N,N′-di(naphthalene-I-yl)-N,N′-diphenyl-benzidine (NPB), 4,4′-cyclohexylidene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), etc.

Also, the hole control layer HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like.

The hole control layer HTR may include the above-described compounds of the hole transport region in at least one of the hole injection layer, the hole transport layer, and/or the hole-side additional layer.

A thickness of the hole control layer HTR may be about 10 nm to about 1000 nm, for example, about 10 nm to about 500 nm. A thickness of the hole injection layer may be, for example, about 5 nm to about 100 nm. A thickness of the hole transport layer may be about 5 nm to about 100 nm. If the hole control layer HTR includes the hole-side additional layer, a thickness of the hole-side additional layer may be about 1 nm to about 100 nm. If a thickness of the hole control layer HTR and a thickness of each layer included therein satisfy the range described above, a satisfactory degree of a hole transport property may be obtained without substantial increase in a driving voltage.

The hole control layer HTR may further include a charge-generating material, in addition to the material mentioned above, to improve conductivity. The charge-generating material may be uniformly or non-uniformly dispersed in the hole control layer HTR. The charge-generating material may be, for example, a p-type dopant. The p-type dopant may include at least one of a halogenated metal compound, a quinone derivative, a metal oxide, or a cyano group-containing compound, but is not limited thereto. For example, the p-type dopant may include a halogenated metal compound such as CuI and/or RbI, a quinone derivative such as tetracyanoquinodimethane (TCNQ) and 2,3,5,6-tetrafluoro-7,7′8,8-tetracyanoquinodimethane (F4-TCNQ), a metal oxide such as tungsten oxide and molybdenum oxide, etc., but the present disclosure is not limited thereto.

The emission layer EML may include a host material and a dopant material. The emission layer EML may include, as a hole transporting host material, a material including a carbazole derivative moiety or an amine derivative moiety. The emission layer EML may include, as an electron transporting host material, a material including a nitrogen-containing aromatic ring structure such as a pyridine derivative moiety, a pyridazine derivative moiety, a pyrimidine derivative moiety, a pyrazine derivative moiety, and/or a triazine derivative moiety.

The emission layer EML may also include, as a host material, an anthracene derivative, a pyrene derivative, a fluoranthene derivative, a chrysene derivative, a dihydrobenzanthracene derivative, a triphenylene derivative, and/or the like. Also, the emission layer EML may further include a typical material known in the art as a host material. For example, the emission layer EML may include, as a host material, at least one of bis[2-(diphenylphosphino)phenyl]ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the present disclosure is not limited thereto, and for example, tris(8-hydroxyquinolino)aluminum (Alq₃), poly(N-vinylcarbazole) (PVK), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material in the emission layer EML.

In one or more embodiments, the emission layer EML may include, as a known fluorescent dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N, N-diphenylamino)pyrene), etc.

In one or more embodiments, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a known phosphorescent dopant material in the emission layer EML. Specifically, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), and/or platinum octaethyl porphyrin (PtOEP) may be used as a phosphorescent dopant.

The electron control layer ETR may have a single-layered structure formed of a single material, a single-layered structure formed of a plurality of materials different from each other, or a multi-layered structure having a plurality of layers formed of a plurality of materials different from each other. For example, at least a portion of the electron control layer ETR may include an electron transport layer and an electron injection layer.

The electron control layer ETR may be formed by using various methods such as a vacuum deposition method, a spin coating method, a casting method, a Langmuir-Blodgett (LB) method, an inkjet printing method, a laser printing method, and/or a laser induced thermal imaging (LITI) method.

The electron control layer ETR may include an anthracene-based compound. However, the present disclosure is not limited thereto, and the electron control layer ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine (T2T), 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAIq), berylliumbis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), and/or a mixture thereof.

Also, the electron control layer ETR may include halogenated metal such as LiF, NaCl, CsF, RbCl, RbI, CuI, and KI, lanthanum group metal such as Yb, and a co-deposition material of the halogenated metal and/or the lanthanum group metal. For example, the electron control layer ETR may include KI:Yb, RbI:Yb, etc. as a co-deposition material. The electron control layer ETR may include two or more materials selected from among Mg, Ag, Yb, and/or Al. For example, the electron control layer ETR may include Mg and Yb.

In one or more embodiments, a metal oxide such as Li₂O and BaO, 8-hydroxyl-lithium quinolate (Liq), or the like may be used in the electron control layer ETR, but the present disclosure is not limited thereto. The electron control layer ETR may also be formed of a mixture of an electron transport material and organo metal salt having an insulating property. The organo metal salt may be a material having an energy band gap of about 4 eV or more. Specifically, for example, the organo metal salt may include metal acetate, metal benzoate, metal acetoacetate, metal acetylacetonate, and/or metal stearate.

The electron control layer ETR may further include at least one of 2,9-dimethyl-4,7-diphenyl-1,10-phenanthroline (BCP) or 4,7-diphenyl-1,10-phenanthroline (Bphen) in addition to the material mentioned above, but the present disclosure is not limited thereto.

The electron control layer ETR may include compounds of the electron transport region described above in the electron injection layer or the electron transport layer. If the electron control layer ETR includes the electron-side additional layer, the material described above may be included in the electron-side additional layer. In one or more embodiments, the electron injection layer may include two or more materials selected from among Mg, Ag, Yb, and/or Al. The electron injection layer may include, for example, a mixture of Mg and Yb.

A thickness of the electron control layer ETR may be, for example, about 10 nm to about 150 nm. A thickness of the electron transport layer may be about 0.1 nm to about 100 nm, for example, about 0.3 nm to about 50 nm. If a thickness of the electron transport layer satisfies the range described above, a satisfactory degree of an electron transport property may be obtained without substantial increase in a driving voltage.

The second electrode CE is provided on the electron control layer ETR. The second electrode CE may be a common electrode. The second electrode CE may be a cathode or an anode, but the present disclosure is not limited thereto. For example, if the first electrode AE is an anode, the second electrode CE may be a cathode, and if the first electrode AE is a cathode, the second electrode CE may be an anode.

The second electrode CE may be a transflective electrode and/or a transmissive electrode. If the second electrode CE is a transmissive electrode, the second electrode CE may be made of a transparent metal oxide, for example, indium tin oxide (ITO), indium zinc oxide (IZO), zinc oxide (ZnO), indium tin zinc oxide (ITZO), etc.

If the second electrode CE is a transflective electrode or a reflective electrode, the second electrode CE may include Ag, Mg, Cu, Al, Pt, Pd, Au, Ni, Nd, Ir, Cr, Li, Ca, LiF/Ca, LiF/AI, Mo, Ti, Yb, W, In, Zn, Sn, and/or a compound or mixture (e.g., AgMg, AgYb, or MgAg) including the same. Alternatively, the second electrode CE may have a multi-layered structure including a transflective film or a reflective film formed of the material and a transparent conductive film formed of indium tin oxide (ITO), indium zinc oxide (IZO), zinc oxide (ZnO), indium tin zinc oxide (ITZO), etc. For example, the second electrode CE may include the metal material described above, a combination of two or more metal materials selected from among the metal materials described above, and/or an oxide of the metal materials described above.

In one or more embodiments, the second electrode CE may be connected to an auxiliary electrode. If the second electrode CE is connected to the auxiliary electrode, resistance of the second electrode CE may decrease.

In one or more embodiments, a capping layer may further be disposed on the second electrode CE of the light-emitting element LED according to one or more embodiments. The capping layer may include multiple layers or a single layer.

In one or more embodiments, the capping layer may be an organic layer and/or an inorganic layer. For example, if the capping layer includes an inorganic material, the inorganic material may include an alkali metal compound such as LiF, an alkaline earth metal compound such as MgF₂, SiON, SiN_{X}, SiOy, etc.

For example, if the capping layer includes an organic material, the organic material may include α-NPD, NPB, TPD, m-MTDATA, Alq₃, CuPc, N4,N4,N4′,N4′-tetra (biphenyl-4-yl) biphenyl-4,4′-diamine (TPD15), 4,4′,4″-tris (carbazol sol-9-yl) triphenylamine (TCTA), etc., and/or include an epoxy resin, and/or acrylate such as methacrylate.

In one or more embodiments, a refractive index of the capping layer may be about 1.6 or more. Specifically, a refractive index of the capping layer with respect to light in a wavelength range of about 550 nm to about 660 nm may be about 1.6 or more.

An encapsulation layer TFE may be disposed on the light-emitting element LED. For example, in one or more embodiments, the encapsulation layer TFE may be disposed on the second electrode CE. In addition, if the light-emitting element LED includes the capping layer, the encapsulation layer TFE may be disposed on the capping layer. The encapsulation layer TFE may include at least one organic film and at least one inorganic film as described above, and the inorganic film and the organic film may be alternately disposed.

The display module DM of an embodiment may include the light control member LCM disposed on the display element layer DP-LED. The light control member LCM may include the light control layer CCL, the color filter layer CFL, and the base layer BL.

The light control layer CCL may include a light converter. The light converter may be a quantum dot, a phosphor, and/or the like. The light converter may convert a wavelength of provided light and emit the light. That is, the light control layer CCL may be a layer of which at least a portion includes a quantum dot and/or a phosphor.

The light control layer CCL may include a plurality of light control patterns CCP-R, CCP-G, and CCP-B. The light control patterns CCP-R, CCP-G, and CCP-B may be spaced (e.g., spaced apart) from each other. The light control patterns CCP-R, CCP-G, and CCP-B may be disposed to be spaced (e.g., spaced apart) from each other with a bank BMP therebetween. The light control patterns CCP-R, CCP-G, and CCP-B may be disposed in bank openings BW-OH defined in the bank BMP. However, the present disclosure is not limited thereto. FIG. 4 illustrates that the bank BMP has a rectangular shape in a cross-sectional view and does not overlap the light control patterns CCP-R, CCP-G, and CCP-B, but in one or more embodiments, an edge of a portion of the light control patterns CCP-R, CCP-G, and CCP-B may at least partially overlap the bank BMP. For example, in one or more embodiments, an edge of a third light control pattern CCP-B may be disposed to overlap the bank BMP in a plan view. In one or more embodiments, the bank BMP may have a trapezoidal shape in a cross-sectional view. In one or more embodiments, the bank BMP may have a shape in which a cross-sectional width increases toward the display element layer DP-LED.

The light control patterns CCP-R, CCP-G, and CCP-B may be a portion that convert a wavelength of light provided from the display element layer DP-LED or transmit the provided light.

The light control layer CCL may include a first light control pattern CCP-R that provides red light that is first light, a second light control pattern CCP-G that provides green light that is second light, and the third light control pattern CCP-B that provides blue light that is third light. The light control layer CCL may include the first light control pattern CCP-R that converts source light provided from the light-emitting element LED into the first light, the second light control pattern CCP-G that converts the source light into the second light, and the third light control pattern CCP-B that transmits the source light. At least a portion of the light control pattern CCP-R, CCP-G, and CCP-B may include a quantum dot that converts the source light into light having a specific wavelength.

In this specification, “a quantum dot” refers to a crystal of a semiconductor compound. A quantum dot may emit light having various emission wavelengths according to a size of a crystal. A quantum dot may also emit light having various emission wavelengths according to adjustment of an element ratio in the quantum compound.

A diameter of the quantum dot may be, for example, about 1 nm to about 10 nm.

The quantum dot may be synthesized by a wet chemical process, a metal organic chemical vapor deposition process, a molecular beam epitaxy process, and/or a process similar thereto.

The wet chemical process is a method of mixing a precursor material with an organic solvent and then growing a quantum dot particle crystal. When the crystal grows, the organic solvent may naturally serve as a dispersant coordinated on a surface of the quantum dot crystal and control growth of the crystal. Thus, through the wet chemical process which is a low-cost process and is easier to perform than a vapor deposition method such as metal organic chemical vapor deposition (MOCVD) and/or molecular beam epitaxy (MBE), growth of a quantum dot particle may be controlled.

A core of the quantum dot may be selected from among a Group II-VI compound, a Group III-V compound, a Group III-VI compound, a Group I-III-VI compound, a Group IV-VI compound, a Group IV element, a Group IV compound, and/or a combination thereof.

The Group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. Meanwhile, a Group II-VI semiconductor compound may further include a Group I metal and/or a Group IV element. A Group I-II-VI compound may be selected from CuSnS and/or CuZnS, and/or ZnSnS, etc. may be selected as a Group II-IV-VI compound. A Group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ and In₂Se₃, a ternary compound such as InGaS₃ and InGaSe₃, and/or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In one or more embodiments, the Group III-V compound may further include a Group II metal. For example, InZnP, etc. may be selected as a Group III-II-V compound.

The Group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof.

An example of the Group II-IV-V semiconductor compound may be a ternary compound selected from the group consisting of ZnSnP, ZnSnP₂, ZnSnAs₂, ZnGeP₂, ZnGeAs₂, CdSnP₂, and CdGeP₂, and/or a mixture thereof.

The Group IV element may be selected from the group consisting of Si, Ge, and a mixture thereof. The Group IV compound may be a binary compound selected from the group consisting of SiC, SiGe, and a mixture thereof.

Each element included in a multi-element compound such as the binary compound, the ternary compound, and/or the quaternary compound may be present in a particle with a uniform concentration or a non-uniform concentration. That is, the formula means a type of an element included in a compound, and an element ratio in the compound may be different. For example, AgInGaS₂ may mean AgInₓGa₁₋ₓS₂ (x is a real number between 0 and 1).

Here, the binary compound, the ternary compound, or the quaternary compound may be present in the particle with a uniform concentration, or may be present in the same particle with partially different concentration distributions. In addition, the quantum dot may have a core/shell structure in which one quantum dot is around (e.g., surrounds) another quantum dot. The core/shell structure may have a concentration gradient in which a concentration of an element present in the shell decreases toward the core.

In one or more embodiments, the quantum dot may have a core-shell structure including a core having the nanocrystal described above and a shell around (e.g., surrounding) the core. The shell of the quantum dot may serve as a protective layer for maintaining a semiconductor property by preventing chemical modification of the core and/or serve as a charging layer for imparting an electrophoretic property to the quantum dot. The shell may be a single layer or multiple layers. An example of the shell of the quantum dot may include a metal or non-metal oxide, a semiconductor compound, and/or a combination thereof.

For example, an example of the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but the present disclosure is not limited thereto.

In addition, an example of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the present disclosure is not limited thereto.

The quantum dot may have a full width of half maximum (FWHM) of an emission wavelength spectrum of about 45 nm or less, preferably about 40 nm or less, and more preferably about 30 nm or less, and within this range, color purity or color reproducibility may be improved. In addition, light emitted through such a quantum dot is emitted in all directions, so that a wide viewing angle may be improved.

In addition, a shape of the quantum dot is not particularly limited to a shape commonly used in the field, but more specifically, the quantum dot may have a shape of a spherical, pyramidal, multi-arm, or cubic nanoparticle, nanotube, nanowire, nanofiber, nanoplatelet particle, etc.

An energy band gap of the quantum dot may be controlled by adjusting a size of the quantum dot or adjusting an element ratio in a quantum compound, and light of various wavelengths may thus be obtained in a quantum dot emission layer. Accordingly, by using the quantum dots (having different sizes or having a varied element ratio in a quantum compound) as described above, a light-emitting element that emits light of various wavelengths may be implemented. Specifically, adjustment of a size of the quantum dot and/or an element ratio in a quantum compound may be selected to emit red, green, and/or blue light. In addition, the quantum dots may be configured such that beams of light of various colors are combined to emit white light.

At least some of the light control patterns CCP-R, CCP-G, and CCP-B may be formed through an inkjet process. In one or more embodiments, the first light control pattern CCP-R and the second light control pattern CCP-G may be formed through the inkjet process. A liquid ink composition may be provided in each of a first bank opening (e.g., BW-OH) and/or a second bank opening, and the provided ink composition may be polymerized through a thermal curing process or a light curing process, and the first light control pattern CCP-R and the second light control pattern CCP-G may be formed. Some of the light control patterns CCP-R, CCP-G, and CCP-B may be formed through a photoresist process. In one or more embodiments, the third light control pattern CCP-B may be formed through the photoresist process. A photoresist composition may be provided in at least a third bank opening, and then the provided photoresist composition may be cured, and the third light control pattern CCP-B may be formed.

The light control layer CCL may further include a scatterer. The first light control pattern CCP-R may include a first quantum dot and a scatterer, the second light control pattern CCP-G may include a second quantum dot and a scatterer, and the third light control pattern CCP-B may not include a quantum dot and may include a scatterer. Each of the first light control pattern CCP-R, the second light control pattern CCP-G, and the third light control pattern CCP-B may further include a base resin for dispersing the quantum dot and/or the scatterer. Because the third light control pattern CCP-B may be formed through a photoresist process as will be described later, the third light control pattern CCP-B may include a photosensitive resin.

The light control layer CCL may include a first barrier layer CAP1 disposed on one surface of the light control patterns CCP-R, CCP-G, and CCP-B. The light control layer CCL may include the first barrier layer CAP1 spaced (e.g., spaced apart) from the display element layer DP-LED with the light control patterns CCP-R, CCP-G, and CCP-B therebetween and a second barrier layer CAP2 adjacent to the display element layer DP-LED.

A step may be formed between a lower surface of the bank BMP and lower surfaces of the light control patterns CCP-R, CCP-G, and CCP-B. That is, the lower surface of the bank BMP may be defined to be lower than the lower surfaces of the light control patterns CCP-R, CCP-G, and CCP-B. A difference in height between the lower surface of the bank BMP and the lower surfaces of the light control patterns CCP-R, CCP-G, and CCP-B may be, for example, about 2 μm to about 3 μm.

The second barrier layer CAP2 may be disposed to follow the step between the bank BMP and the light control patterns CCP-R, CCP-G, and CCP-B. The second barrier layer CAP2 may be directly disposed on a filling layer FML.

The light control member LCM in the display module DM includes the color filter layer CFL disposed on the light control layer CCL. The color filter layer CFL may include color filters CF1, CF2, and CF3. The color filter layer CFL may include a first color filter CF1 that transmits first light, a second color filter CF2 that transmits second light, and a third color filter CF3 that transmits source light (e.g., third light). In one or more embodiments, the first color filter CF1 may be a red filter, the second color filter CF2 may be a green filter, and the third color filter CF3 may be a blue filter.

Each of the color filters CF1, CF2, and CF3 includes a polymer photosensitive resin and/or a colorant. The first color filter CF1 may include a red colorant, the second color filter CF2 may include a green colorant, and the third color filter CF3 may include a blue colorant. The first color filter CF1 may include a red pigment and/or red dye, the second color filter CF2 may include a green pigment and/or green dye, and the third color filter CF3 may include a blue pigment and/or blue dye.

The first to third color filters CF1, CF2, and CF3 may be disposed to respectively correspond to the first pixel region PXA-R, the second pixel region PXA-B, and the third pixel region PXA-G. Also, the first to third color filters CF1, CF2, and CF3 may be disposed to respectively correspond to the first to third light control patterns CCP-R, CCP-B, and CCP-G.

In addition, the plurality of color filters CF1, CF2, and CF3 that transmit different light may be disposed to overlap each other in correspondence to a peripheral region NPXA disposed between the pixel regions PXA-R, PXA-B, and PXA-G. The plurality of color filters CF1, CF2, and CF3 may be disposed to overlap each other in a third direction DR3, which is a thickness direction, to define boundaries between adjacent pixel regions PXA-R, PXA-B, and PXA-G. In one or more embodiments, the color filter layer CFL may include a light blocking portion to define boundaries between adjacent color filters CF1, CF2, and CF3. The light blocking portion may be formed of a blue filter or may be formed of an inorganic light blocking material or an organic light blocking material containing a black pigment and/or black dye.

The display module DM according to one or more embodiments may include a low refractive layer LR. The low refractive layer LR may be disposed between the light control layer CCL and the color filter layer CFL. The low refractive layer LR may be disposed above the light control layer CCL or the first barrier layer CAP1 and prevent the light control patterns CCP-R, CCP-G, and CCP-B from being exposed to moisture and/or oxygen. In addition, the low refractive layer LR may be disposed between the light control patterns CCP-R, CCP-G, and CCP-B and the color filters CF1, CF2, and CF3 and function as an optical functional layer that increases light extraction efficiency, prevents reflected light from being incident to the light control layer CCL, and/or the like. The low refractive layer LR may be a layer having a lower refractive index compared to an adjacent layer.

The low refractive layer LR may include at least one inorganic layer. For example, the low refractive layer LR may include silicon nitride, aluminum nitride, zirconium nitride, titanium nitride, hafnium nitride, tantalum nitride, silicon oxide, aluminum oxide, titanium oxide, tin oxide, cerium oxide, and/or silicon oxynitride, and/or include a metal thin film having light transmittance, etc. However, the present disclosure is not limited thereto, and the low refractive layer LR may include an organic film. The low refractive layer LR may have, for example, a structure in which a plurality of hollow particles are dispersed in an organic polymer resin. The low refractive layer LR may be composed of a single layer or a plurality of layers.

The display module DM of an embodiment may include the filling layer FML disposed between the light control member LCM and the display panel DP.

In one or more embodiments, the filling layer FML may fill a gap between the display element layer DP-LED and the light control layer CCL. The filling layer FML may be directly disposed on the encapsulation layer TFE, and the second barrier layer CAP2 may be directly disposed on the filling layer FML. A lower surface of the filling layer FML may be in contact with an upper surface of the encapsulation layer TFE, and an upper surface of the filling layer FML may be in contact with a lower surface of the second barrier layer CAP2.

The filling layer FML may function as a buffer between the display element layer DP-LED and the light control layer CCL. In one or more embodiments, the filling layer FML may function to absorb impact, etc., and may increase the strength of the display module DM. The filling layer FML may be formed from a filling resin including a polymer resin. For example, the filling layer FML may be formed from a filling layer resin including an acrylic resin, an epoxy-based resin, and/or the like.

In one or more embodiments, the filling layer FML may also be disposed between the light control layer CCL and the color filter layer CFL. The filling layer FML may be disposed above the light control layer CCL and prevent the light control patterns CCP-R, CCP-G, and CCP-B from being exposed to moisture and/or oxygen. In addition, the filling layer FML may be disposed between the light control patterns CCP-R, CCP-G, and CCP-B and the color filters CF1, CF2, and CF3 and function as an optical functional layer that increases light extraction efficiency, prevents reflected light from being incident to the light control layer CCL, and/or the like. The filling layer FML may be a layer having a lower refractive index compared to adjacent other layers.

In one or more embodiments, the light control member LCM may further include the base layer BL disposed on the color filter layer CFL. The base layer BL may be a member that provides a base surface on which the color filter layer CFL, the light control layer CCL, and/or the like are disposed. The base layer BL may be a glass substrate, a metal substrate, a plastic substrate, etc. However, the present disclosure is not limited thereto, and the base layer BL may be an inorganic layer, an organic layer, and/or a composite material layer. Also, in one or more embodiments, the base layer BL may be omitted.

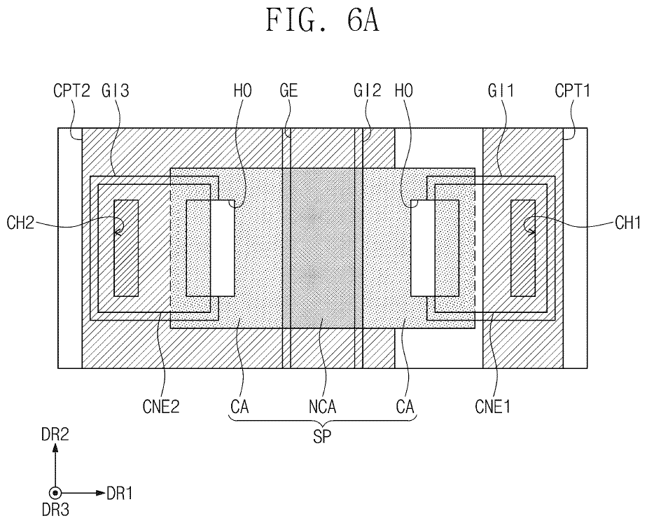

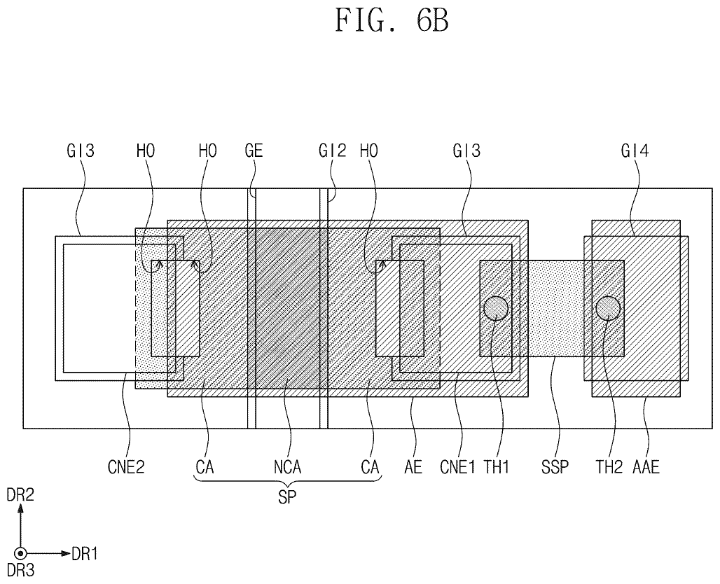

FIG. 5 is a cross-sectional view of a display panel according to one or more embodiments of the present disclosure. FIG. 5 illustrates a cross section mainly focused on connection relationship of a light-emitting element LED and a transistor TR included in one pixel of the display panel shown in FIG. 3. FIGS. 6A and 6B each are a plan view of some components of a display panel according to one or more embodiments of the present disclosure. FIG. 6A illustrates a plane corresponding to connection electrodes CNE1 and CNE2, the transistor TR, a first conductive pattern CPT1, and a second conductive pattern CPT2 in FIG. 5. FIG. 6B illustrates a plane corresponding to the connection electrodes CNE1 and CNE2, the transistor TR, a first electrode AE, a sensing pattern SSP, and an additional electrode AAE in FIG. 5. Hereinafter, a display panel DP according to one or more embodiments of the present disclosure will be described with reference to FIGS. 5, 6A, and 6B.

Referring to FIG. 5, the display panel DP may include a base layer BS, a circuit element layer DP-CL, a display element layer DP-LED, and an encapsulation layer TFE.

The circuit element layer DP-CL may include the conductive patterns CPT1 and CPT2 disposed on the base layer BS, the transistor TR, the connection electrodes CNE1 and CNE2, a buffer layer BFL, a gate insulating pattern layer GIL, insulating layers INS1 and INS2, a sensing line SGL, the sensing pattern SSP, and a capacitor Cst.

Each of the first conductive pattern CPT1 and the second conductive pattern CPT2 may have a multi-layered structure. The first conductive pattern CPT1 and the second conductive pattern CPT2 may be formed of the same material and have the same stacked structure. For example, each of the first conductive pattern CPT1 and the second conductive pattern CPT2 may include a first pattern layer PT1 and a second pattern layer PT2 stacked on the base layer BS in a thickness direction (e.g., the third directions DR3). However, f the present disclosure is not limited thereto, and each of the first and second conductive patterns CPT1 and CPT2 may have a single-layered structure, or may also have a multi-layered structure in which three or more pattern layers are stacked.

A thickness of the first pattern layer PT1 and a thickness of the second pattern layer PT2 may be different. For example, the thickness of the first pattern layer PT1 may be smaller than the thickness of the second pattern layer PT2. However, the present disclosure is not limited thereto.

Each of the first pattern layer PT1 and the second pattern layer PT2 may include molybdenum (Mo), aluminum (Al), chromium (Cr), gold (Au), titanium (Ti), nickel (Ni), neodymium (Nd), and/or copper (Cu), and/or alloy thereof. For example, the first pattern layer PT1 may include titanium (Ti), and the second pattern layer PT2 may include copper (Cu). However, the present disclosure is not limited thereto.

The buffer layer BFL may be disposed on the base layer BS to cover the first and second conductive patterns CPT1 and CPT2. The buffer layer BFL may include at least one inorganic film. In this specification, the buffer layer BFL may be referred to as “a lower insulating layer”.

Referring to FIGS. 5 and 6A together, the transistor TR may include a semiconductor pattern SP and a gate electrode GE. The semiconductor pattern SP may be disposed on the buffer layer BFL. Bonding force between the semiconductor pattern SP and the base layer BS may be improved by the buffer layer BFL. The semiconductor pattern SP may include a semiconductor material such as polysilicon, crystalline silicon, and/or a metal oxide.

A source region S-A, an active region A-A, and a drain region D-A of the transistor TR may be formed from the semiconductor pattern SP. An electrical property of the semiconductor pattern SP may be changed according to whether the semiconductor pattern is doped or not or whether a metal oxide is reduced or not. The source region S-A and the drain region D-A of the semiconductor pattern SP having relatively high conductivity may serve as an electrode or a signal line. A region of the semiconductor pattern SP which is not doped or is doped with a low concentration, or in which a metal oxide is not reduced may correspond to the active region A-A having low conductivity.

Conductive regions CA may be spaced (e.g., spaced apart) from each other with a non-conductive region NCA therebetween in a plan view. The conductive regions CA may respectively correspond to the source region S-A and the drain region D-A of the semiconductor pattern SP, and the non-conductive region NCA may correspond to a channel region of the semiconductor pattern SP.

At least one hole HO may be defined in the semiconductor pattern SP. The hole HO may be formed during an etching process through which the connection electrodes CNE1 and CNE2 and the gate electrode GE are formed. FIG. 5 illustrates as an example that holes HO spaced (e.g., spaced apart) from each other are formed in the semiconductor pattern SP. One hole HO from among the holes HO may be surrounded by the source region S-A in a plan view, and another hole HO may be surrounded by the drain region D-A. However, the present disclosure is not limited thereto, and according to a process for the circuit element layer DP-CL, the hole HO may not be formed in the semiconductor pattern SP.

The gate insulating pattern layer GIL may be disposed on the buffer layer BFL. The gate insulating pattern layer GIL may include at least one inorganic film. The gate insulating pattern layer GIL may include first to third insulating patterns GI1, GI2, and GI3 spaced (e.g., spaced apart) from each other. The first insulating pattern GI1 may cover a portion of the drain region D-A and may be disposed on the first conductive pattern CPT1. The second insulating pattern GI2 may be disposed on the active region A-A. The third insulating pattern GI3 may cover a portion of the source region S-A and may be disposed on the second conductive pattern CPT2.

The connection electrodes CNE1 and CNE2 may include a first connection electrode CNE1 and a second connection electrode CNE2. The first connection electrode CNE1 may be disposed on the first insulating pattern GI1. The first connection electrode CNE1 may be connected to the first conductive pattern CPT1 through a first contact hole CH1 passing through the buffer layer BFL and the first insulating pattern GI1. The first connection electrode CNE1 may be in contact with a portion of the drain region D-A and connected to the drain region D-A. The drain region D-A and the first conductive pattern CPT1 may be electrically connected to each other through the first connection electrode CNE1. Because the first conductive pattern CPT1 having excellent conductivity is connected to the drain region D-A, a current transmitting property of the semiconductor pattern SP may be improved.

The second connection electrode CNE2 may be disposed on the third insulating pattern GI3. The second connection electrode CNE2 may be connected to the second conductive pattern CPT2 through a second contact hole CH2 passing through the buffer layer BFL and the third insulating pattern GI3. The second connection electrode CNE2 may be in contact with a portion of the source region S-A and connected to the source region S-A. The source region S-A and the second conductive pattern CPT2 may be electrically connected to each other through the second connection electrode CNE2. The second connection electrode CNE2 may be connected to a power line which provides power to the light-emitting element LED and provide a first voltage to the transistor TR.

The gate electrode GE may be disposed on the second insulating pattern GI2. The gate electrode GE may overlap the active region A-A in a plan view and may be spaced (e.g., spaced apart) from the semiconductor pattern SP with the second insulating pattern GI2 therebetween in a thickness direction (e.g., the third direction DR3).

The connection electrodes CNE1 and CNE2 and the gate electrode GE may be spaced (e.g., spaced apart) from each other in a plan view. Each of the connection electrodes CNE1 and CNE2 and the gate electrode GE may have a multi-layered structure in which conductive layers ML1, ML2, and ML3 including materials different from each other are stacked. The conductive layers ML1, ML2, and ML3 may include first to third conductive layers ML1, ML2, and ML3. The first to third conductive layers ML1, ML2, and ML3 may be stacked through a sputtering process, but the present disclosure is not limited thereto.

The first to third conductive layers ML1, ML2, and ML3 may each include a metal material. For example, the first to third conductive layers ML1, ML2, and ML3 may each include molybdenum (Mo), aluminum (Al), chromium (Cr), gold (Au), titanium (Ti), nickel (Ni), neodymium (Nd), copper (Cu), and/or indium tin oxide ITO, and/or alloy thereof. The first to third conductive layers ML1, ML2, and ML3 may include metal materials different from each other. The second conductive layer ML2 may include a metal material having excellent conductivity, and the first and third conductive layers ML1 and ML3 respectively disposed under and on the second conductive layer ML2 may include a metal material having corrosion resistance. For example, the first conductive layer ML1 may include titanium (Ti), the second conductive layer ML2 may include copper (Cu), and the third conductive layer ML3 may include indium tin oxide ITO. However, the present disclosure is not limited thereto.

Thicknesses of the first to third conductive layers ML1, ML2, and ML3 may be different from each other. For example, a thickness of the second conductive layer ML2 including a material having high conductivity may be the largest of the first to third conductive layers ML1, ML2, and ML3. Thus, the gate electrode GE and the connection electrodes CNE1 and CNE2 that are formed from the first to third conductive layers ML1, ML2, and ML3 may have a property of low resistance and high conductivity.

FIG. 5 illustrates as an example that the connection electrodes CNE1 and CNE2 and the gate electrode GE each have a multi-layered structure of three layers, but the present disclosure is not limited thereto. Each of the connection electrodes CNE1 and CNE2 and the gate electrode GE may have a single-layered structure, or may also have a two-layered structure or a multi-layered structure of four or more layers.

The connection electrodes CNE1 and CNE2 and the gate electrode GE may be concurrently (e.g., simultaneously) formed through the same process. The connection electrodes CNE1 and CNE2 and the gate electrode GE may have the same stacked structure. For example, the connection electrodes CNE1 and CNE2 and the gate electrode GE may have a three-layered structure of Ti/Cu/ITO. Because the connection electrodes CNE1 and CNE2 and the gate electrode GE may be concurrently (e.g., simultaneously) formed through the same process, the display panel DP may be manufactured through a simplified process.

A first insulating layer INS1 may be disposed on the gate insulating pattern layer GIL and the buffer layer BFL to cover the connection electrodes CNE1 and CNE2 and the gate electrode GE. A second insulating layer (or an insulating layer) INS2 may be disposed on the first insulating layer INS1. Each of the first insulating layer INS1 and the second insulating layer INS2 may include at least one inorganic film or an organic film. The inorganic film may include aluminum oxide, titanium oxide, silicon oxide, silicon nitride, silicon oxynitride, zirconium oxide, and/or hafnium oxide, but is not limited to the material. The organic film may include a phenol-based polymer, an acrylic polymer, an imide-based polymer, an arylether-based polymer, an amide-based polymer, a fluorine-based polymer, a p-xylene-based polymer, a vinyl alcohol-based polymer, and/or a combination thereof, but is not limited to the material.

The display element layer DP-LED may be disposed on the circuit element layer DP-CL. The display element layer DP-LED may include a pixel-defining layer PDL and the light-emitting element LED. As one example, the light-emitting element LED may include an organic light-emitting element, an inorganic light-emitting element, a quantum dot light-emitting element, a micro-LED light-emitting element, and/or a nano-LED light-emitting element. However, the present disclosure is not limited thereto, and the light-emitting element LED may include various embodiments as long as light may be generated or the amount of light may be controlled in response to an electrical signal.

The pixel-defining layer PDL may be disposed on the second insulating layer INS2 of the circuit element layer DP-CL. The pixel-defining layer PDL may include a polymer resin. For example, the pixel-defining layer PDL may include a polyacrylate-based resin and/or a polyimide-based resin. The pixel-defining layer PDL may further include an inorganic material in addition to the polymer resin. In addition, the pixel-defining layer PDL may be formed of an inorganic material. For example, the pixel-defining layer PDL may include silicon nitride (SiN_{X}), silicon oxide (SiOₓ), silicon oxynitride (SiOₓN_{y}), and/or the like.

In one or more embodiments, the pixel-defining layer PDL may include a light-absorbing material. The pixel-defining layer PDL may include a black coloring agent. The black coloring agent may include black dye or a black pigment. The black coloring agent may include carbon black, metal such as chromium, and/or an oxide thereof. However, the pixel-defining layer PDL is not limited to the example.

The light-emitting element LED may include the first electrode AE, an emission layer EML, and a second electrode CE that are sequentially stacked. The description provided above with reference to FIG. 4 may be applied to the light-emitting element LED. For convenience of description, the hole control layer HTR and the electron control layer ETR described above with reference to FIG. 4 from among components of the light-emitting element LED are not illustrated in FIG. 5.

The first electrode AE may be disposed on the second insulating layer INS2 of the circuit element layer DP-CL. The first electrode AE may be electrically connected to the first connection electrode CNE1. The first electrode AE may be connected to the first connection electrode CNE1 through a first through-hole TH1 passing through the first insulating layer INS1, the second insulating layer INS2, and a sensing pattern SSP. A portion of the first electrode AE may be disposed in the first through-hole TH1. Because the first electrode AE may be connected to the first connection electrode CNE1, the drain region D-A may be connected to the light-emitting element LED through the first connection electrode CNE1.

A light-emitting opening OH that exposes at least a portion of the first electrode AE may be defined in the pixel-defining layer PDL. A portion of the first electrode AE exposed by the light-emitting opening OH may correspond to a pixel region PXA-R, PXA-B, and PXA-G. A region in which the pixel-defining layer PDL is disposed may correspond to a peripheral region NPXA. The peripheral region NPXA may be around (e.g., may surround) the pixel region PXA.

The encapsulation layer TFE may cover the light-emitting element LED. The encapsulation layer TFE may encapsulate the display element layer DP-LED. The encapsulation layer TFE may include at least one insulating film. The encapsulation layer TFE according to one or more embodiments may include at least one inorganic film (hereinafter, an inorganic encapsulation film). The encapsulation layer TFE according to one or more embodiments may include inorganic encapsulation films and at least one organic film (hereinafter, an organic encapsulation film) disposed between the inorganic encapsulation films.

The inorganic encapsulation film may protect the display element layer DP-LED from moisture and/or oxygen, and the organic encapsulation film may protect the display element layer DP-LED from foreign substances such as dust particles. The inorganic encapsulation film may include silicon nitride, silicon oxynitride, silicon oxide, titanium oxide, aluminum oxide, and/or the like, however, the present disclosure is not limited thereto. The organic encapsulation film may include an acrylic compound, an epoxy-based compound, etc. The organic encapsulation film may include a photopolymerizable organic material and is not particularly limited.

In one or more embodiments, the display panel DP includes the sensing line SGL. The sensing line SGL may be a line that is electrically connected to the sensing pattern SSP described below and transfers a level of the amount of light of the light-emitting element LED measured through the sensing pattern SSP, so that whether optical compensation is performed or not may be determined according to the level of the amount of light.

The sensing line SGL and each of the connection electrodes CNE1 and CNE2 and the gate electrode GE are disposed on (e.g., at) the same layer. The gate insulating pattern layer GIL may include a fourth insulating pattern GI4, and the sensing line SGL may be disposed on the fourth insulating pattern GI4. The fourth insulating pattern GI4 may be disposed on an additional pattern SP-a. The additional pattern SP-a may be disposed on the buffer layer BFL and formed through the same process as that for the semiconductor pattern SP. In one or more embodiments, the additional pattern SP-a may be omitted, and the fourth insulating pattern GI4 may be directly disposed on the buffer layer BFL.

The sensing line SGL may be spaced (e.g., spaced apart) from each of the connection electrodes CNE1 and CNE2 and the gate electrode GE in a plan view. The sensing line SGL may have a multi-layered structure in which the conductive layers ML1, ML2, and ML3 described above are stacked.

The sensing line SGL, the connection electrodes CNE1 and CNE2, and the gate electrode GE may be concurrently (e.g., simultaneously) formed through the same process. The sensing line SGL and each of the connection electrodes CNE1 and CNE2 and the gate electrode GE may have the same stacked structure. For example, the sensing line SGL, the connection electrodes CNE1 and CNE2, and the gate electrode GE may have a three-layered structure of Ti/Cu/ITO. Because the sensing line SGL, the connection electrodes CNE1 and CNE2, and the gate electrode GE may be concurrently (e.g., simultaneously) formed through the same process, the display panel DP may be manufactured through a simplified process.

Referring to FIGS. 5 and 6B together, the display panel DP according to one or more embodiments includes the sensing pattern SSP and the additional electrode AAE. The sensing pattern SSP is disposed on the first insulating layer INS1. The additional electrode AAE is disposed on the second insulating layer INS2. The additional electrode AAE and the first electrode AE of the light-emitting element LED are disposed on (e.g., at) the same layer.

The sensing pattern SSP is disposed on the first insulating layer INS1 and is patterned in a partial region. The sensing pattern SSP overlaps at least a portion of the first electrode AE and a portion of the additional electrode AAE in a plan view. The sensing pattern SSP may overlap a portion of the first connection electrode CNE1 and a portion of the sensing line SGL in a plan view.

The sensing pattern SSP includes silicon (Si). The sensing pattern SSP may include silicon and/or nitrogen. In one or more embodiments, the sensing pattern SSP may include amorphous silicon. The sensing pattern SSP may be a deposition pattern formed by providing source gas including silicon and/or source gas including nitrogen together.

In a visible light wavelength range, a light transmittance of the sensing pattern SSP may be about 10% or more. In a visible light wavelength range, a light transmittance of the sensing pattern SSP may be about 10% to about 20%. As used herein, a light transmittance is a value indicating a degree of light absorption of a material layer. Specifically, a light transmittance represents a value obtained by dividing an intensity of transmission light incident from the outside by an intensity of incident light. Because the light transmittance of the sensing pattern SSP may be limited to the range, the sensing pattern SSP may provide high sensing sensitivity for measuring the amount of light of the light-emitting element LED by absorbing the light emitted from the light-emitting element LED.

The sensing pattern SSP is disposed on the first insulating layer INS1 and is covered with the second insulating layer INS2. The second insulating layer INS2 covering the sensing pattern SSP may be a layer having a high transmittance in a visible light wavelength range. In one or more embodiments, a light transmittance of the second insulating layer INS2 in a visible light wavelength range may be about 80% or more. A light transmittance of the second insulating layer INS2 may be about 80% to about 95%. Because the second insulating layer INS2 may have a high light transmittance, light emitted from the light-emitting element LED may not be blocked by the second insulating layer INS2 and may be introduced into the sensing pattern SSP.

The additional electrode AAE is disposed on the second insulating layer INS2 and is disposed to be spaced (e.g., spaced apart) from the first electrode AE in a plan view. The additional electrode AAE may be spaced (e.g., spaced apart) from the first electrode AE along a first direction DR1.

The additional electrode AAE and the first electrode AE are disposed on (e.g., at) the same layer. The additional electrode AAE and the first electrode AE may be concurrently (e.g., simultaneously) formed through the same process. The additional electrode AAE and the first electrode AE may have the same (e.g., substantially the same) stacked structure. For example, each of the additional electrode AAE and the first electrode AE may have a three-layered structure of ITO/Ag/ITO. Because the additional electrode AAE and the first electrode AE may be concurrently (e.g., simultaneously) formed through the same process, the display panel DP may be manufactured through a simplified process.

The pixel-defining layer PDL may be disposed on the additional electrode AAE. At least a portion of the additional electrode AAE may be covered with the pixel-defining layer PDL. The additional electrode AAE may be entirely covered with the pixel-defining layer PDL. An additional opening for exposing an upper surface of the additional electrode AAE may not be formed in the pixel-defining layer PDL. However, the present disclosure is not limited thereto, and in one or more embodiments, a portion of the upper surface of the additional electrode AAE may also be exposed through an opening defined in the pixel-defining layer PDL.

The additional electrode AAE may be electrically connected to the sensing line SGL. The additional electrode AAE may be connected to the sensing line SGL through a second through-hole TH2 passing through the first insulating layer INS1 and the second insulating layer INS2 and the sensing pattern SSP. A portion of the additional electrode AAE may be disposed in the second through-hole TH2.

In one or more embodiments, each of the first through-hole TH1 and the second through-hole TH2 may pass through the sensing pattern SSP disposed on the first insulating layer INS1. Each of the first through-hole TH1 and the second through-hole TH2 may pass through all of the first insulating layer INS1, the second insulating layer INS2, and the sensing pattern SSP. Each of the first through-hole TH1 and the second through-hole TH2 may pass through the sensing pattern SSP, a portion of the first electrode AE may be disposed in the first through-hole TH1, and a portion of the additional electrode AAE may be disposed in the second through-hole TH2. Thus, each of the first electrode AE and the additional electrode AAE may be electrically connected to the sensing pattern SSP.

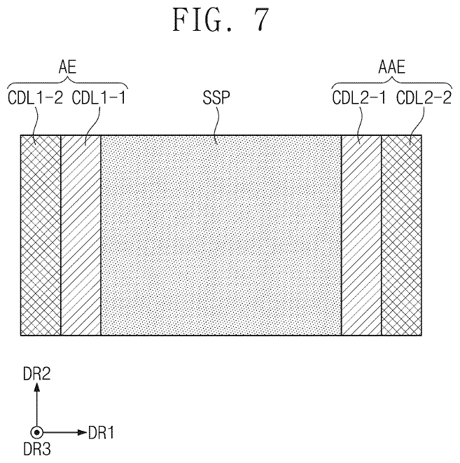

FIG. 7 is a plan view of some components of a display panel according to one or more embodiments of the present disclosure. FIG. 7 schematically illustrates a planar arrangement relationship of a sensing pattern SSP, a first electrode AE, and an additional electrode AAE.

Referring to FIGS. 5, 6B, and 7, the first electrode AE disposed in the first through-hole TH1, the additional electrode AAE disposed in the second through-hole TH2, and the sensing pattern SSP may be electrically connected and function as a diode. Each of the first electrode AE and the additional electrode AAE may include a plurality of conductive patterns. The first electrode AE may include a (1-1)-th conductive pattern CDL1-1 and a (1-2)-th conductive pattern CDL1-2, and the additional electrode AAE may include a (2-1)-th conductive pattern CDL2-1 and a (2-2)-th conductive pattern CDL2-2. Each of the (1-1)-th conductive pattern CDL1-1 and the (2-1)-th conductive pattern CDL2-1 may include a transparent conductive oxide such as indium tin oxide (ITO). Each of the (1-2)-th conductive pattern CDL1-2 and the (2-2)-th conductive pattern CDL2-2 may include conductive metal such as silver (Ag).

The first electrode AE, the additional electrode AAE, and the sensing pattern SSP disposed to be adjacent to each other may form a simulated structure of a Schottky diode. In the simulated structure of a Schottky diode formed by the first electrode AE, the additional electrode AAE, and the sensing pattern SSP, a current path may be formed in the sensing pattern SSP due to a voltage difference between the first electrode AE and the additional electrode AAE, and then the sensing pattern SSP may sense the amount of a portion of light generated from the light-emitting element LED. Then, the sensing line SGL may transfer a level of the amount of light of the light-emitting element LED measured through the sensing pattern SSP, and whether optical compensation is performed or not may be determined according to the level of the amount of light.

The display panel DP according to one or more embodiments may form a simulated structure of a Schottky diode through a structure in which the sensing pattern SSP is disposed on the first insulating layer INS1 and the first electrode AE and the additional electrode AAE are electrically connected to the sensing pattern SSP to measure the amount of light of the light-emitting element LED, and thus whether optical compensation is performed or not may be determined according to a degree of deterioration of the light-emitting element LED, thereby improving light emission efficiency and power consumption of the display panel DP. More specifically, the display panel DP according to one or more embodiments may sense the amount of light travelling in a downward direction which is a direction opposite to a third direction DR3 of light generated from the light-emitting element LED through a structure in which the sensing pattern SSP is covered with an insulating layer disposed under the first electrode AE and the additional electrode AAE, and the first electrode AE and the additional electrode AAE are electrically connected to the sensing pattern SSP, measure the initial amount of light of the light-emitting element and the amount of light of the light-emitting element after a suitable time (e.g., a predetermined time) since initial light emission, and calculate a degree of deterioration of light from the light-emitting element LED on the basis of the measured amounts of light. Thus, through a simulated structure of a Schottky diode formed by the sensing pattern SSP, the first electrode AE, and the additional electrode AAE, the display panel DP according to one or more embodiments may check a degree of deterioration of light from the light-emitting element LED and determine whether optical compensation is performed or not, and thus light emission efficiency and power consumption of the display panel DP may be improved.

Referring back to FIG. 5, the circuit element layer DP-CL of the display panel DP according to one or more embodiments may further include the capacitor Cst. The capacitor Cst may be charged with charge, the amount of which corresponds to a difference between a voltage corresponding to a data signal and a power voltage received from a power line. The transistor TR described above may control a driving current flowing through the light-emitting element LED according to the amount of charge stored in the capacitor Cst.

Turn-on time of the transistor TR may be determined according to the amount of charge charged in the capacitor Cst. The light-emitting element LED may emit light during a turn-on period of the transistor TR.

A first capacitor electrode E1 defines one electrode of the capacitor Cst. The first capacitor electrode E1 and the conductive patterns CPT1 and CPT2 may be disposed on (e.g., at) the same layer. The first capacitor electrode E1 may also be a pattern having an integrated shape with the conductive patterns CPT1 and CPT2. Alternatively, the conductive patterns CPT1 and CPT2 and the first capacitor electrode E1 may also be electrically connected to each other through an additional bridge electrode, and may also be spaced (e.g., spaced apart) from each other and receive different voltages.

A second capacitor electrode E2 overlaps the first capacitor electrode E1 in a plan view. The second capacitor electrode E2 and the first capacitor electrode E1 may form a capacitor with the buffer layer BFL and a fifth insulating pattern GI5 therebetween.

In this embodiment, the second capacitor electrode E2, the connection electrodes CNE1 and CNE2, the gate electrode GE, and the sensing line SGL may be disposed on (e.g., at) the same layer. The second capacitor electrode E2 may be disposed on the gate insulating pattern layer GIL. The gate insulating pattern layer GIL may include the fifth insulating pattern GI5, and the second capacitor electrode E2 may be disposed on the fifth insulating pattern GI5. The second capacitor electrode E2, the connection electrodes CNE1 and CNE2, the gate electrode GE, and the sensing line SGL may be concurrently (e.g., simultaneously) formed through one mask. Thus, the second capacitor electrode E2, the connection electrodes CNE1 and CNE2, the gate electrode GE, and the sensing line SGL may include the same material and have the same stacked structure.

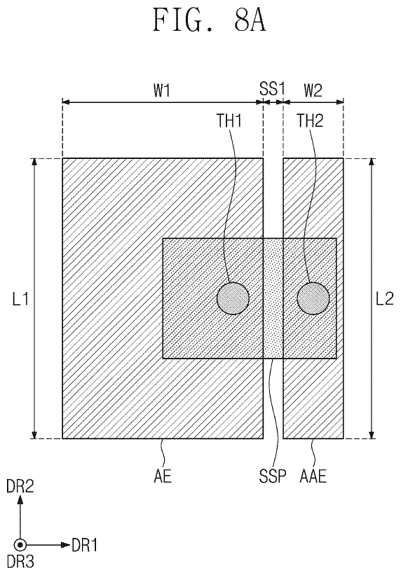

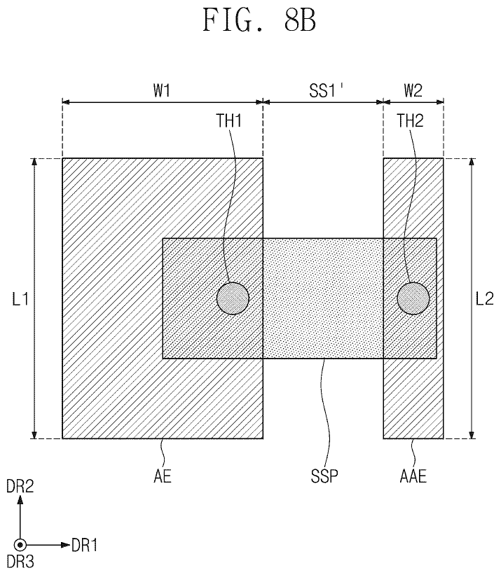

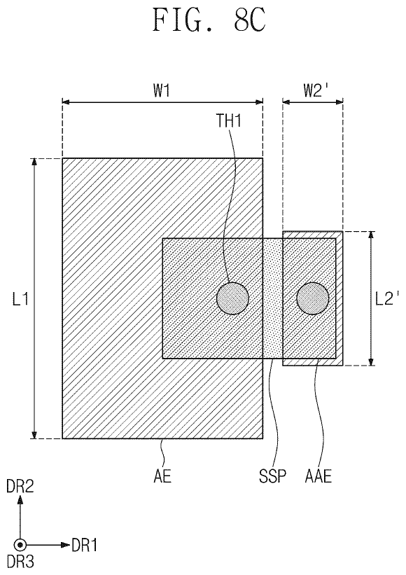

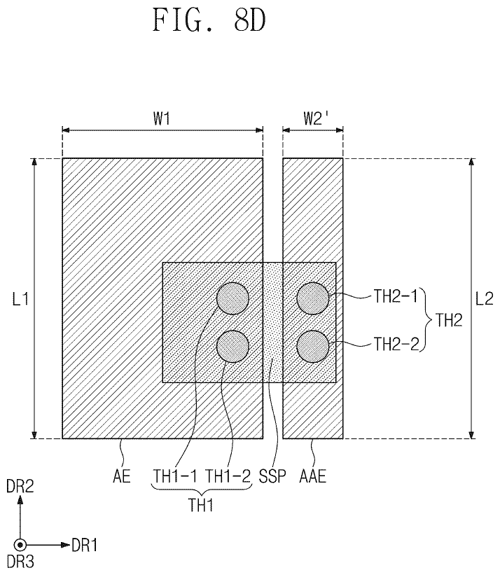

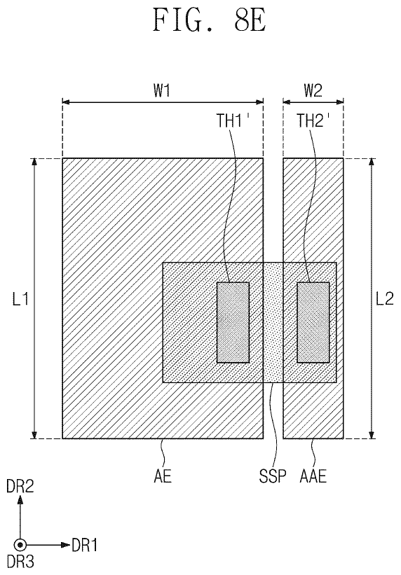

FIGS. 8A-8E each are a plan view of some components of a display panel according to one or more embodiments of the present disclosure. FIGS. 8A-8E each schematically illustrate a planar arrangement relationship of a sensing pattern SSP, a first electrode AE, and an additional electrode AAE, an arrangement relationship of through-holes TH1 and TH2, and/or the like.

Referring to FIG. 8A, the sensing pattern SSP overlaps at least a portion of the first electrode AE and a portion of the additional electrode AAE in a plan view. The additional electrode AAE is disposed to be spaced (e.g., spaced apart) from the first electrode AE in a plan view. The additional electrode AAE may be spaced (e.g., spaced apart) from the first electrode AE along a first direction DR1.

In a plan view, each of the sensing pattern SSP, the first electrode AE, and the additional electrode AAE may have a rectangular shape. Each of the sensing pattern SSP, the first electrode AE, and the additional electrode AAE may have a rectangular shape having sides respectively extending in the first direction DR1 and a second direction DR2.

The additional electrode AAE may have a smaller area size than the first electrode AE in a plan view. The first electrode AE may have a first width W1 in the first direction DR1, the additional electrode AAE may have a second width W2 in the first direction DR1, and the first width W1 may be greater than the second width W2.

The additional electrode AAE may be spaced (e.g., spaced apart) from the first electrode AE by a first distance SS1 in the first direction DR1. In one or more embodiments, the first distance SS1 may be smaller than a width of each of the additional electrode AAE and the first electrode AE in the first direction DR1. That is, the first distance SS1 may be smaller than the first width W1 and the second width W2.

However, the present disclosure is not limited thereto, and as illustrated in FIG. 8B, a first distance SS1′ may be greater than a width of at least one of the additional electrode AAE or the first electrode AE in a first direction DR1. The first distance SS1′ may be greater than a second width W2 of the additional electrode AAE. If the first distance SS1′ is designed to be greater than the second width W2, etc., an area size of the sensing pattern SSP not overlapping the additional electrode AAE and the first electrode AE may increase, thereby improving performance of the sensing pattern SSP for sensing light generated from the light-emitting element LED (see FIG. 5).

Referring back to FIG. 8A, the first electrode AE may have a first length L1 in the second direction DR2, the additional electrode AAE may have a second length L2 in the second direction DR2, and the first length L1 and the second length L2 may be substantially the same. As used herein, widths, lengths, and/or the like being “substantially the same” includes not only a case in which widths, lengths, and/or the like have physically the same figure, but also a case in which, despite the same design of widths, lengths, and/or the like, there is a difference therebetween which falls within a margin of error in a process.

However, the present disclosure is not limited thereto, and as illustrated in FIG. 8C, a length of the first electrode AE in a second direction DR2 and a length of the additional electrode AAE in the second direction DR2 may be different. In the second direction DR2, a second length L2′ of the additional electrode AAE may be smaller than a first length L1 of the first electrode AE. As illustrated in FIG. 8C, both a width (W2′) of the additional electrode AAE in a first direction DR1 and the length (L2′) of the additional electrode AAE in the second direction DR2 may be designed to be smaller than a width (W1) and length (L1) of the first electrode AE, and a planar area size of the additional electrode AAE may thus be reduced or minimized.

One first through-hole TH1 and one second through-hole TH2 may be provided and may each have a circular shape in a plan view. However, the present disclosure is not limited thereto, and as illustrated in FIG. 8D, a first through-hole TH1 and a second through-hole TH2 may each be provided in plurality. The first through-hole TH1 may include a (1-1)-th sub through-hole TH1-1 and a (1-2)-th sub through-hole TH1-2 spaced (e.g., spaced apart) from each other along the second direction DR2, and the second through-hole TH2 may include a (2-1)-th sub through-hole TH2-1 and a (2-2)-th sub through-hole TH2-2 spaced (e.g., spaced apart) from each other along the second direction DR2. In one or more embodiments, the number of each of the first through-hole TH1 and the second through-hole TH2 provided may be three or more, and each of the first through-hole TH1 and the second through-hole TH2 may also be arranged along a first direction DR1.

In addition, a first through-hole TH1′ and a second through-hole TH2′ may each have a polygonal shape, not a circular shape, in a plan view. As illustrate in FIG. 8E, the first through-hole TH1′ and the second through-hole TH2′ may each have a rectangular shape. The first through-hole TH1′ and the second through-hole TH2′ may each have a rectangular shape having a long side in a second direction DR2 and a short side in a first direction DR1. However, the first through-hole TH1′ and the second through-hole TH2′ may each also have various shapes different from what is illustrated in FIG. 8E. For example, the first through-hole TH1′ and the second through-hole TH2′ may each have a rectangular shape having a rounded corner.

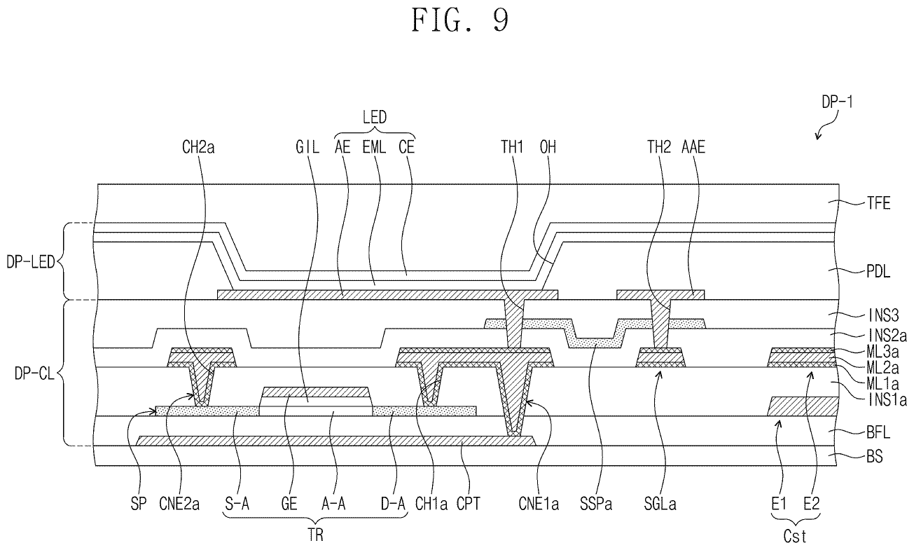

FIG. 9 is a cross-sectional view of a display panel according to one or more embodiments of the present disclosure. FIG. 9 illustrates a display panel according to one or more embodiments different from the display panel according to the embodiment illustrated in FIG. 5. Descriptions overlapping with the above descriptions of other embodiments may not be provided.

Referring to FIG. 9, a display panel DP-1 may include a base layer BS, a circuit element layer DP-CL, a display element layer DP-LED, and an encapsulation layer TFE.

The circuit element layer DP-CL may include conductive patterns CPT disposed on the base layer BS, a transistor TR, connection electrodes CNE1a and CNE2a, a buffer layer BFL, a gate insulating pattern layer GIL, insulating layers INS1a, INS2a, and INS3, a sensing line SGLa, a sensing pattern SSPa, and a capacitor Cst.

A conductive pattern CPT may be disposed on the base layer BS. The conductive pattern CPT may receive a bias voltage. The conductive pattern CPT may also receive a first voltage. The conductive pattern CPT may prevent electrical potential caused by polarization from affecting the transistor TR. The conductive pattern CPT may prevent external light from reaching the transistor TR. In one or more embodiments of the present disclosure, the conductive pattern CPT may also be a floating electrode isolated from another electrode or wiring. The conductive pattern CPT may be disposed to correspond to the transistor TR. The conductive pattern CPT may include metal, e.g., molybdenum.

A first connection electrode CNE1a may be disposed on a first insulating layer INS1a. The first connection electrode CNE1a may be in contact with a portion of a drain region D-A through a first contact hole CH1a passing through the first insulating layer INS1a and connected to the drain region D-A. In addition, the first connection electrode CNE1a may be connected to the conductive pattern CPT through a contact hole passing through the buffer layer BFL and the first insulating layer INS1a. The drain region D-A and the conductive pattern CPT may be electrically connected to each other through the first connection electrode CNE1a. Because the conductive pattern CPT having excellent conductivity is connected to the drain region D-A, a current transmitting property may be improved.

A second connection electrode CNE2a may be disposed on the first insulating layer INS1a. The second connection electrode CNE2a may be connected to a source region S-A through a second contact hole CH2a passing through the first insulating layer INS1a. The second connection electrode CNE2a may be connected to a power line that supplies power to a light-emitting element LED and provide a first voltage to the transistor TR.

A sensing line SGLa may be disposed on the first insulating layer INS1a. The sensing line SGLa may be a line that is electrically connected to the sensing pattern SSPa and transfers a level of the amount of light of the light-emitting element LED measured through the sensing pattern SSPa, so that whether optical compensation is performed or not may be determined according to the level of the amount of light.

The sensing line SGLa and the connection electrodes CNE1a and CNE2a are disposed on (e.g., at) the same layer. The sensing line SGLa and the connection electrodes CNE1a and CNE2a may be directly disposed on the first insulating layer INS1a.

The sensing line SGLa may be spaced (e.g., spaced apart) from the connection electrodes CNE1a and CNE2a in a plan view. The sensing line SGLa may have a multi-layered structure in which the conductive layers ML1a, ML2a, and ML3a, similar to the conductive layers ML1, ML2, and ML3 described above are stacked.

The sensing line SGLa and the connection electrodes CNE1a and CNE2a may be concurrently (e.g., simultaneously) formed through the same process. The sensing line SGLa and each of the connection electrodes CNE1a and CNE2a may have the same (e.g., substantially the same) stacked structure. The sensing line SGLa and each of the connection electrodes CNE1a and CNE2a may have a multi-layered structure in which conductive layers ML1a, ML2a, and ML3a including different materials are stacked. The conductive layers ML1a, ML2a, and ML3a may include first to third conductive layers ML1a, ML2a, and ML3a. The first to third conductive layers ML1a, ML2a, and ML3a may be stacked through a sputtering process, but the present disclosure is not limited thereto.

Each of the first to third conductive layers ML1a, ML2a, and ML3a may include a metal material. For example, each of the first to third conductive layers ML1a, ML2a, and ML3a may include molybdenum (Mo), aluminum (Al), chromium (Cr), gold (Au), titanium (Ti), nickel (Ni), neodymium (Nd), copper (CU), and/or indium tin oxide (ITO), and/or alloy thereof. The first to third conductive layers ML1a, ML2a, and ML3a may include different metal materials. The second conductive layer ML2a may include a metal material having excellent conductivity, and the first and third conductive layers ML1a and ML3a respectively disposed under and on the second conductive layer ML2a may include a metal material having corrosion resistance. For example, the first conductive layer ML1a may include titanium (Ti), the second conductive layer ML2a may include copper (Cu), and the third conductive layer ML3a may include indium tin oxide (ITO). However, the present disclosure is not limited thereto.

A gate electrode GE may be disposed on the gate insulating pattern layer GIL. The gate electrode GE may overlap an active region A-A in a plan view and may be spaced (e.g., spaced apart) from the active region A-A with the gate insulating pattern layer GIL therebetween in a thickness direction (e.g., the third direction DR3).

The connection electrodes CNE1a and CNE2a and the gate electrode GE may be spaced (e.g., spaced apart) from each other in a plan view. The connection electrodes CNE1a and CNE2a and the gate electrode GE may include different materials. That is, unlike the connection electrodes CNE1 and CNE2 and the gate electrode GE illustrated in FIG. 5, the connection electrodes CNE1a and CNE2a and the gate electrode GE may be formed through separate processes.

A first electrode AE may be disposed on a third insulating layer INS3 of the circuit element layer DP-CL. The first electrode AE may be connected to the first connection electrode CNE1a through a first through-hole TH1 passing through a second insulating layer INS2a, a sensing pattern SSPa, and the third insulating layer INS3. A portion of the first electrode AE may be disposed in the first through-hole TH1. Because the first electrode AE may be connected to the first connection electrode CNE1a, the drain region D-A may be connected to the light-emitting element LED through the first connection electrode CNE1a.

The sensing pattern SSPa may be disposed on the second insulating layer INS2a and covered with the third insulating layer INS3. An additional electrode AAE is disposed on the third insulating layer INS3. The additional electrode AAE and the first electrode AE are disposed on (e.g., at) the same layer.

The sensing pattern SSPa is disposed on the second insulating layer INS2a and is patterned in a partial region. The sensing pattern SSPa overlaps at least a portion of the first electrode AE and a portion of the additional electrode AAE in a plan view. The sensing pattern SSPa may overlap a portion of the first connection electrode CNE1a and a portion of the sensing line SGLa in a plan view.

The third insulating layer INS3 covering the sensing pattern SSPa and the second insulating layer INS2a may be a layer having a high transmittance in a visible light wavelength range. In one or more embodiments, a light transmittance of the third insulating layer INS3 in a visible light wavelength range may be about 80% or more. A light transmittance of the third insulating layer INS3 may be about 80% to about 95%. Because the third insulating layer INS3 may have a high light transmittance, light emitted from the light-emitting element LED may not be blocked by the third insulating layer INS3 and may be introduced into the sensing pattern SSPa.

The additional electrode AAE is disposed on the third insulating layer INS3, and is disposed to be spaced (e.g., spaced apart) from the first electrode AE in a plan view. The additional electrode AAE may be spaced (e.g., spaced apart) from the first electrode AE along a first direction DR1.

The additional electrode AAE and the first electrode AE may be disposed on (e.g., at) the same layer. The additional electrode AAE and the first electrode AE may be concurrently (e.g., simultaneously) formed through the same process.

A pixel-defining layer PDL may be disposed on the additional electrode AAE. At least a portion of the additional electrode AAE may be covered with the pixel-defining layer PDL. The additional electrode AAE may be entirely covered with the pixel-defining layer PDL.

The additional electrode AAE may be electrically connected to the sensing line SGLa. The additional electrode AAE may be connected to the sensing line SGLa through a second through-hole TH2 passing through the second insulating layer INS2a, the sensing pattern SSPa, and the third insulating layer INS3. A portion of the additional electrode AAE may be disposed in the second through-hole TH2.

Each of the first through-hole TH1 and the second through-hole TH2 may pass through the sensing pattern SSPa disposed on the second insulating layer INS2a. Each of the first through-hole TH1 and the second through-hole TH2 may pass through all of the second insulating layer INS2a, the third insulating layer INS3, and the sensing pattern SSPa. Each of the first through-hole TH1 and the second through-hole may pass through the sensing pattern SSPs, a portion of the first electrode AE may be disposed in the first through-hole TH1, and a portion of the additional electrode AAE may be disposed in the second through-hole TH2. Accordingly, each of the first electrode AE and the additional electrode AAE may be electrically connected to the sensing pattern SSPa. In one or more embodiments, as shown in FIG. 9, the sensing pattern SSPa may have a shape in which a central portion of the sensing pattern SSPa may be bent or curved and may be inserted into the second insulating layer INS2a. However, the present disclosure is not limited thereto.

Hereinafter, a manufacturing method of a display panel according to one or more embodiments of the present disclosure will be described.

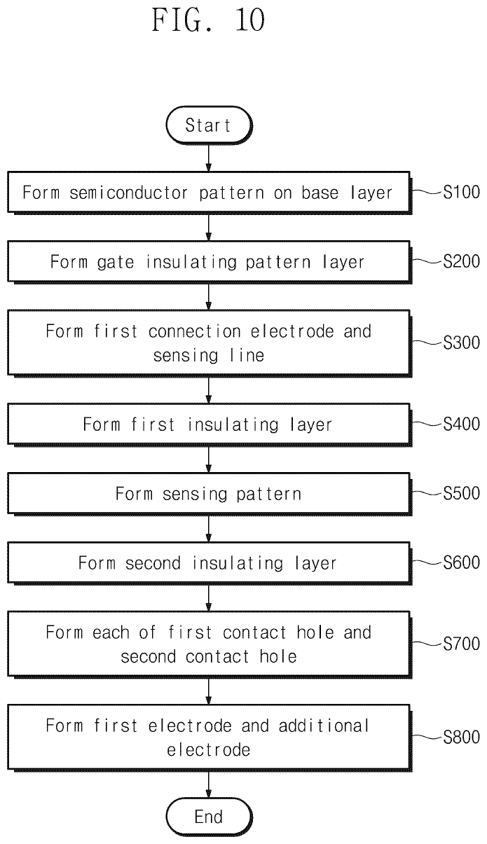

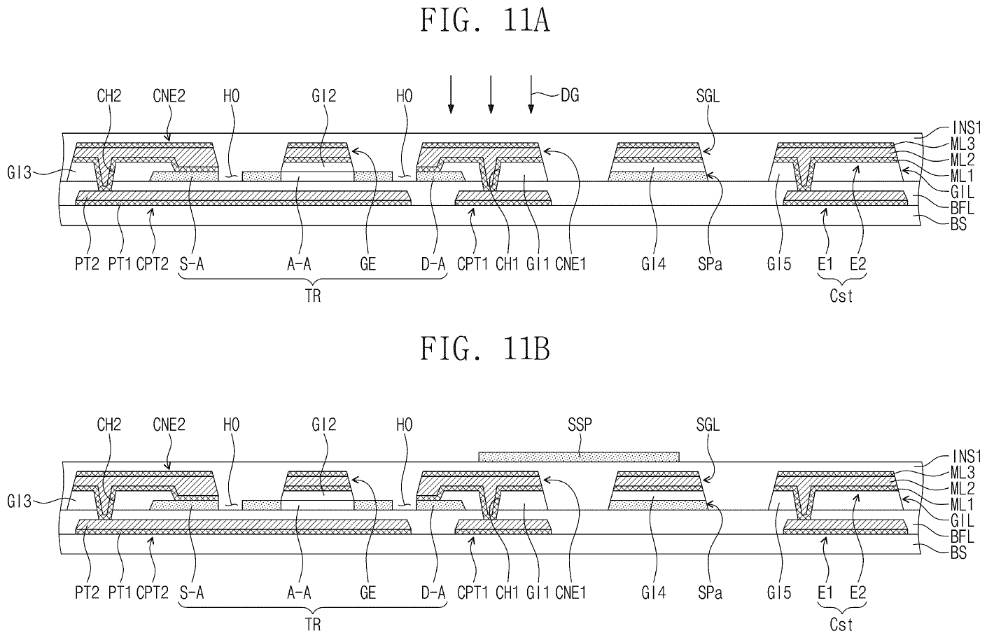

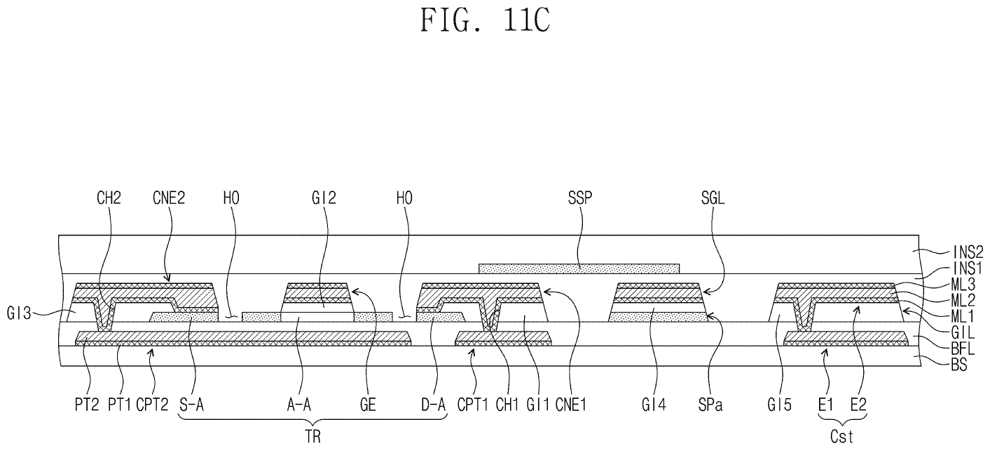

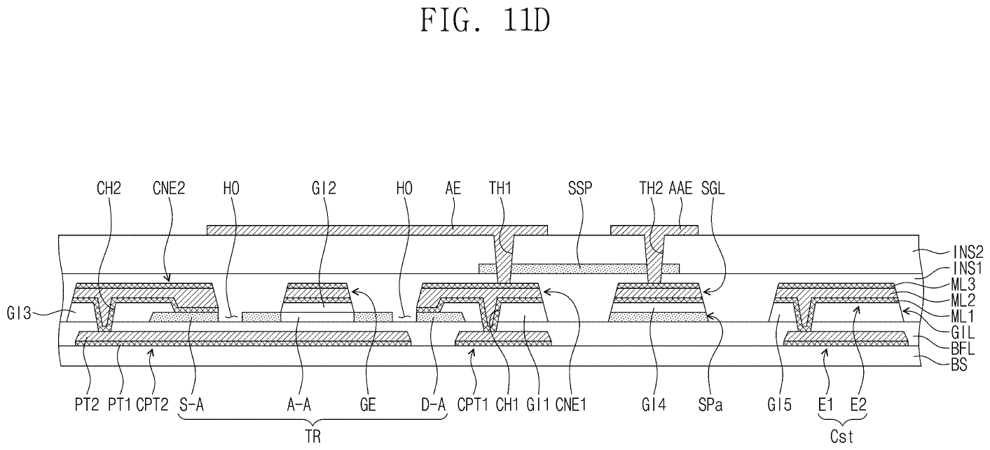

FIG. 10 is a flowchart of a manufacturing method of a display panel according to one or more embodiments of the present disclosure. FIGS. 11A-11D are cross-sectional views of some steps of a manufacturing method of a display panel. FIGS. 11A-11D each illustrate a state of some steps of a manufacturing method of a display panel in a cross section corresponding to the cross section illustrated in FIG. 5.

Referring to FIG. 10, a manufacturing method of a display panel according to one or more embodiments includes forming a semiconductor pattern on a base layer (S100), forming a gate insulating pattern layer covering a portion of the semiconductor pattern (S200), forming a first connection electrode and a sensing line on the gate insulating pattern layer (S300), forming a first insulating layer covering the first connection electrode and the sensing line (S400), forming a sensing pattern including silicon on the first insulating layer (S500), forming a second insulating layer covering the sensing pattern (S600), forming each of a first through-hole and a second through-hole passing through the first insulating layer, the sensing pattern, and the second insulating layer (S700), and forming, on the second insulating layer, a first electrode connected to the first connection electrode through the first through-hole and an additional electrode connected to the sensing line through the second through-hole (S800).

FIGS. 11A-11D illustrate cross sections corresponding to the forming of the sensing pattern including silicon on the first insulating layer (S500), the forming of the second insulating layer covering the sensing pattern (S600), the forming of each of the first through-hole and the second through-hole passing through the first insulating layer, the sensing pattern, and the second insulating layer (S700), and the forming of the first electrode connected to the first connection electrode through the first through-hole and the additional electrode connected to the sensing line through the second through-hole on the second insulating layer (S800) in the manufacturing method of the display panel.

Referring to FIGS. 10, 11A, and 11B together, in the manufacturing method of the display panel according to one or more embodiments, a sensing pattern SSP is formed on a first insulating layer INS1. The sensing pattern SSP may be formed by providing source gas DG to form a sensing pattern layer and then patterning the sensing pattern layer. The sensing pattern SSP may be patterned to overlap at least a portion of each of a first connection electrode CNE1 and a sensing line SGL.

The source gas DG may include nitrogen (N₂) gas and/or silane (SiH₄) gas. The source gas DG may include nitrogen (N₂) gas, ammonia (NH₃) gas, silane (SiH₄) gas, and hydrogen (H₂) gas. The sensing pattern SSP may be formed by providing each of nitrogen (N₂) gas, ammonia (NH₃) gas, silane (SiH₄) gas, and/or hydrogen (H₂) gas through chemical vapor deposition CVD to form a deposition film and then patterning the deposition film through a dry etching process, etc. In the source gas DG, a ratio of nitrogen gas to silane gas may be about 4.0 to about 10. Because a ratio of nitrogen gas to silane gas in the source gas DG may be limited to the range, the sensing pattern SSP formed through the source gas DG may provide high sensing sensitivity for measuring the amount of light of the light-emitting element LED by absorbing the light emitted from the light-emitting element LED.

Referring to FIGS. 10, 11B, and 11C, in the manufacturing method of the display panel according to one or more embodiments, a second insulating layer INS2 is formed on the first insulating layer INS1 and the sensing pattern SSP. The second insulating layer INS2 may include an organic material. The second insulating layer INS2 covering the sensing pattern SSP may be formed of a material having high transmittance in a visible light wavelength range. In one or more embodiments, a light transmittance of the second insulating layer INS2 in a visible light wavelength range may be about 80% or more. A light transmittance of the second insulating layer INS2 may be about 80% to about 95%.

Referring to FIGS. 10, 11C, and 11D, in the manufacturing method of the display panel according to one or more embodiments, each of a first through-hole TH1 and a second through-hole TH2 is formed. Each of the first through-hole TH1 and the second through-hole TH2 may be formed to pass through all of the first insulating layer INS1, the second insulating layer INS2, and the sensing pattern SSP. The first through-hole TH1 and the second through-hole TH2 may be formed through the same process.

After forming the through-holes TH1 and TH2, a first electrode AE and an additional electrode AAE are formed. The first electrode AE may be formed to be connected to the first connection electrode CNE1 through the first through-hole TH1. The additional electrode AAE may be formed to be connected to the sensing line SGL through the second through-hole TH2. The first electrode AE and the additional electrode AAE may be formed through the same process. The first electrode AE and the additional electrode AAE may include the same material. Each of the first electrode AE and the additional electrode AAE may be formed by forming a deposition layer which has an integrated shape and a portion of which is disposed in the through-holes TH1 and TH2, and then patterning the deposition layer. The first through-hole TH1 and the second through-hole TH2 may each pass through the sensing pattern SSP, a portion of the first electrode AE may be disposed in the first through-hole TH1, and a portion of the additional electrode AAE may be disposed in the second through-hole TH2. Thus, each of the first electrode AE and the additional electrode AAE may be electrically connected to the sensing pattern SSP.

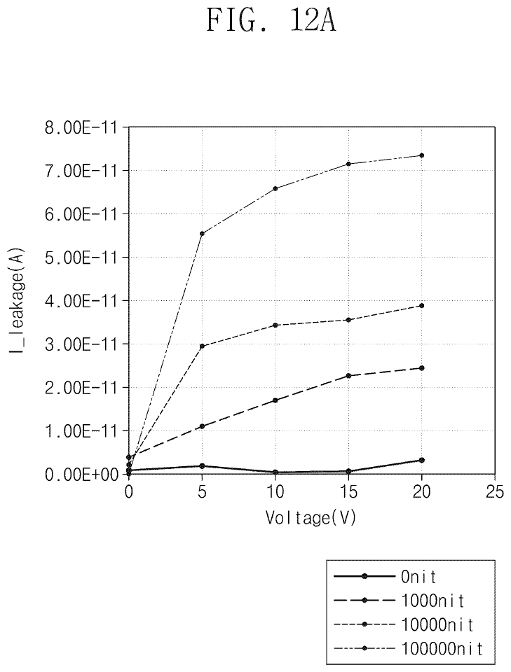

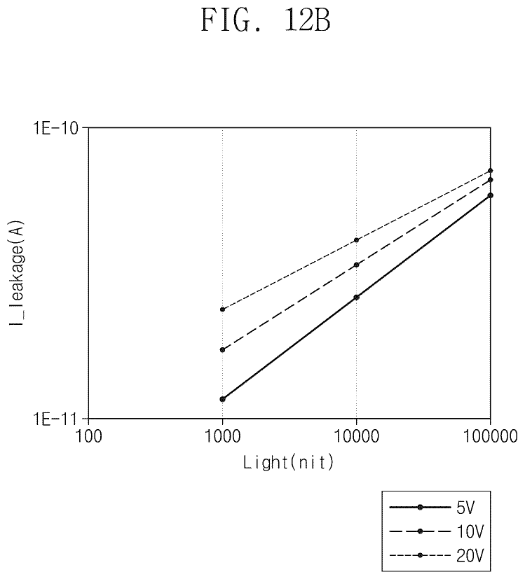

FIG. 12A is a graph showing a value of a leakage current compared to a voltage of a sensing pattern according to the amount of emitted light of a light-emitting element in a display panel according to one or more embodiments. FIG. 12B is a graph showing a value of a leakage current compared to the amount of emitted light of a light-emitting element according to a voltage applied to a sensing pattern in a display panel according to one or more embodiments. FIG. 12B shows each of the amount of emitted light and a leakage current on a logarithmic scale.

Referring to the graphs in FIGS. 12A and 12B, it may be seen that as the amount of emitted light of the light-emitting element increases, a value of a leakage current generated in the sensing pattern increases in direct proportion to the amount of emitted light. Through the graphs in FIGS. 12A and 12B, it may be seen that the display panel according to one or more embodiments of the present disclosure may measure the amount of light of the light-emitting element by forming a simulated structure of a Schottky diode through a structure in which the sensing pattern is provided below the light-emitting element and a first electrode and an additional electrode are electrically connected to the sensing pattern as described above. Thus, the display panel according to one or more embodiments may have improved light emission efficiency and power consumption.

According to one or more embodiments of the present disclosure, a degree of deterioration of a light-emitting element may be measured by providing a simulated structure of a diode in a circuit element layer of a display panel, and whether optical compensation is performed or not may be determined according to the degree of deterioration of the light-emitting element, thereby improving light emission efficiency and power consumption of the display panel. In addition, the simulated structure of a diode may be formed in the circuit element layer through a simple process without an additional doping process, etc., thereby improving efficiency of a display panel manufacturing process.

Although description has been made with reference to the embodiments of the present disclosure, it is understood that the present disclosure should not be limited to these embodiments, but various changes and modifications may be made by one ordinary skilled in the art within the spirit and scope of the present disclosure as hereinafter claimed. Therefore, the technical scope of the present disclosure is not limited to the contents described in the detailed description of the specification, but should be determined by the accompanying claims and their equivalents.

What is claimed is:

1. A display panel comprising:
a base layer;
a transistor on the base layer and comprising a semiconductor pattern;
a first connection electrode connected to the semiconductor pattern;
a sensing line at a same layer as the first connection electrode;
a first insulating layer on the transistor and the first connection electrode;
a second insulating layer on the first insulating layer;
a first electrode on the second insulating layer and connected to the first connection electrode through a first through-hole;
an additional electrode on the second insulating layer, the additional electrode being spaced from the first electrode in a plan view, and connected to the sensing line through a second through-hole; and
a sensing pattern on the first insulating layer, the sensing pattern being electrically connected to the first electrode and the additional electrode, and comprising silicon.

2. The display panel of claim 1, wherein a light transmittance of the sensing pattern in a visible light wavelength range is about 10% or more.

3. The display panel of claim 1, further comprising a gate insulating pattern layer on the semiconductor pattern,
wherein each of the first connection electrode and the sensing line is on the gate insulating pattern layer.

4. The display panel of claim 3, wherein the transistor further comprises a gate electrode on the gate insulating pattern layer.

5. The display panel of claim 4, wherein the first connection electrode, the sensing line, and the gate electrode comprise a same material.

6. The display panel of claim 1, wherein the sensing pattern further comprises nitrogen.

7. The display panel of claim 1, further comprising:
an intermediate layer on the first electrode and comprising an emission layer; and
a second electrode on the intermediate layer.

8. The display panel of claim 1, wherein the first electrode and the additional electrode are spaced from each other along a first direction, and
a width of the first electrode in the first direction is greater than a width of the additional electrode in the first direction.

9. The display panel of claim 8, wherein a distance between the first electrode and the additional electrode in the first direction is greater than the width of the additional electrode in the first direction.

10. The display panel of claim 8, wherein a length of the first electrode in a second direction crossing the first direction is substantially the same as a length of the additional electrode in the second direction.

11. The display panel of claim 1, wherein each of the first through-hole and the second through-hole passes through each of the first insulating layer, the second insulating layer, and the sensing pattern.

12. The display panel of claim 11, wherein each of the first through-hole and the second through-hole includes a plurality of through-holes.

13. The display panel of claim 11, wherein the first electrode and the additional electrode are spaced from each other along a first direction, and
wherein each of the first through-hole and the second through-hole includes:
a long side extending in a second direction crossing the first direction, and
a short side extending in the first direction.

14. The display panel of claim 1, further comprising:
a lower insulating layer between the base layer and the transistor; and
a plurality of conductive patterns between the lower insulating layer and the base layer and spaced from each other in a plan view,
wherein at least a portion of the plurality of conductive patterns is electrically connected to the first connection electrode.

15. The display panel of claim 1, further comprising a pixel-defining layer on the second insulating layer and having a pixel opening located therein and exposing at least a portion of the first electrode,
wherein the additional electrode is covered with the pixel-defining layer.

16. The display panel of claim 1, wherein a light transmittance of the second insulating layer in a visible light wavelength range is about 80% or more.

17. A display panel comprising:
a base layer;
a transistor on the base layer and comprising a semiconductor pattern;
a first connection electrode connected to the semiconductor pattern;
a sensing line spaced from the first connection electrode in a plan view;
a first insulating layer on the transistor and the first connection electrode;
a second insulating layer on the first insulating layer;
a light-emitting element on the second insulating layer and electrically connected to the first connection electrode;
an additional electrode on the second insulating layer and connected to the sensing line; and
a sensing pattern on the first insulating layer,
wherein the light-emitting element comprises:
a first electrode on the second insulating layer, connected to the first connection electrode, and spaced from the additional electrode in a plan view;
an emission layer on the first electrode; and
a second electrode on the emission layer, and
wherein a portion of each of the first electrode and the additional electrode is in a through-hole in the sensing pattern.

18. The display panel of claim 17, further comprising a pixel-defining layer on the second insulating layer and having a pixel opening defined therein and exposing at least a portion of the first electrode,
wherein the additional electrode is covered with the pixel-defining layer.

19. A manufacturing method of a display panel, the manufacturing method comprising:
forming a semiconductor pattern on a base layer;
forming a gate insulating pattern layer covering a portion of the semiconductor pattern;
forming a first connection electrode and a sensing line on the gate insulating pattern layer;
forming a first insulating layer covering the first connection electrode and the sensing line;
forming a sensing pattern comprising silicon on the first insulating layer;
forming a second insulating layer covering the sensing pattern;
forming each of a first through-hole and a second through-hole passing through the first insulating layer, the sensing pattern, and the second insulating layer; and
forming, on the second insulating layer, a first electrode connected to the first connection electrode through the first through-hole, and an additional electrode connected to the sensing line through the second through-hole.

20. The manufacturing method of claim 19, wherein in the forming of the sensing pattern, nitrogen (N₂) gas and silane (SiH₄) gas are provided, and
a ratio of the nitrogen gas to the silane gas is about 4.0 to about 10.
